(19) United States
(12) Patent Application Publication
(10) Pub. No.: US 2011/0123913 A1
(43) Pub. Date: May 26, 2011

(54) EXPOSURE APPARATUS, EXPOSING METHOD, AND DEVICE FABRICATING METHOD

(75) Inventor: Hiromitsu YOSHIMOTO, Saitama-shi (JP)

(73) Assignee: NIKON CORPORATION, TOKYO (JP)

(21) Appl. No.: 12/947,903

(22) Filed: Nov. 17, 2010

Related U.S. Application Data
(60) Provisional application No. 61/272,926, filed on Nov. 19, 2009.

(51) Int. Cl. G03F 7/20; G03B 27/58

(52) U.S. Cl. 430/30; 430/325; 355/72

(57) ABSTRACT

An exposure apparatus includes: a first moving body, which comprises guide members that extend in a first direction, moves in a second direction, which is substantially orthogonal to the first direction; two second moving bodies, which are provided such that they are capable of moving in the first direction along the guide members, move in the second direction together with the guide members by the movement of the first moving body; a holding apparatus holds the object and is supported by the two second moving bodies such that it is capable of moving within a two dimensional plane that includes at least the first directions and the second directions; and a transport apparatus, which comprises a chuck member that can noncontactually hold the object from above, transports the object to and from the holding apparatus.

### CROSS-REFERENCE TO RELATED APPLICATION

This application is a non-provisional application claiming priority to and the benefit of U.S. provisional application No. 61/272,926, filed on Nov. 19, 2009. The entire contents of which are incorporated herein by reference.

### BACKGROUND

The present invention relates to an exposure apparatus, an exposing method, and a device fabricating method.

Conventionally, lithographic processes that fabricate electronic devices (i.e., microdevices), such as semiconductor devices (i.e., integrated circuits and the like) and liquid crystal display devices, principally use step-and-repeat type projection exposure apparatuses (i.e., so-called steppers), step-and-scan type projection exposure apparatuses (i.e., so-called scanning steppers or scanners), or the like.

Wafers that undergo exposure and substrates like glass plates that are used in various exposure apparatuses have been increasing in size with time (e.g., wafers have increased in size every 10 years). Presently, the mainstream wafer has a diameter of 300 mm, and the era of a wafer with a diameter of 450 mm is nearing (e.g., refer to International Technology Roadmap for Semiconductors, 2007 Edition). When the industry transitions to the 450 mm wafer, the number of dies (i.e., chips) yielded by one wafer will increase to more than double that of the current 300 mm wafer, which will help reduce costs. In addition, it is anticipated that the effective utilization of energy, water, and other resources will further reduce the total resources consumed per chip.

Nevertheless, because the thickness of a wafer does not increase in proportion to its size, the strength of a 450 mm wafer is markedly less than that of a 300 mm wafer. Accordingly, it is expected that transporting or picking up a single wafer with the same means and methods used for the current 300 mm wafers will be difficult.

Accordingly, it is expected that new systems capable of handling 450 mm wafers will appear.

### SUMMARY

A first aspect of the present invention provides an exposure apparatus that radiates an energy beam to form a pattern on an object and that comprises: a first moving body, which comprises guide members that extend in a first direction, that moves in a second direction, which is substantially orthogonal to the first direction; two second moving bodies, which are provided such that they are capable of moving in the first direction along the guide members, that move in the second direction together with the guide members by the movement of the first moving body; a holding apparatus, which holds the object and is supported by the two second moving bodies such that it is capable of moving within a two dimensional plane that includes at least the first direction and the second direction; and a transport apparatus, which comprises a chuck member that can noncontactually hold the object from above, that transports the object to and from the holding apparatus.

A second aspect of the present invention provides an exposing method that radiates an energy beam to form a pattern on an object and that comprises: a step that moves a first moving body, which comprises guide members that extend in a first direction, in a second direction, which is orthogonal to the first direction; a step that moves two second moving bodies, which are provided such that they are capable of moving in the first direction along the guide members, in the second direction together with the guide members by the movement of the first moving body; a step that supports a holding apparatus, which holds the object, by the two second moving bodies, synchronously moves the two second moving bodies along the guide members, and moves the holding apparatus in the first direction; and a step that uses a chuck member, which is capable of noncontactually holding the object from above, to transport the object to and from the holding apparatus.

A third aspect of the present invention provides a device fabricating method that comprises the steps of: exposing an object using an exposing method as recited above; and developing the exposed object.

Aspects of the present invention can be adapted to either the loading of a thin plate shaped object onto a holding apparatus or the unloading of the thin plate shaped object from the holding apparatus, or both.

### BRIEF DESCRIPTION OF THE DRAWINGS

FIG. 1 schematically shows the configuration of an exposure apparatus of one embodiment.

FIG. 2 is a partial plan view that schematically shows the exposure apparatus shown in FIG. 1.

FIG. 3 is an external oblique view of a wafer stage provided by the exposure apparatus shown in FIG. 1.

FIG. 4 is an exploded view of a part of the wafer stage.

FIG. 5 is an enlarged view of the vicinity of a measurement station in FIG. 1.

FIG. 6A is a side view, viewed from the direction, that shows the wafer stage provided by the exposure apparatus shown in FIG. 1.

FIG. 6B is a plan view that shows the wafer stage.

FIG. 7 is a view for explaining a movable blade provided by the exposure apparatus in FIG. 1.

FIG. 8 is a block diagram that shows the configuration of a control system of the exposure apparatus shown in FIG. 1.

FIG. 9 is a plan view that shows the arrangement of magnet units and a coil unit that constitute a fine motion stage drive system.

FIG. 10A is a view for explaining the operation performed when a fine motion stage is rotated around the Z axis with respect to coarse motion stages.

FIG. 10B is a view for explaining the operation performed when the fine motion stage is rotated around the Y axis with respect to the coarse motion stages.

FIG. 10C is a view for explaining the operation performed when the fine motion stage is rotated around the X axis with respect to the coarse motion stages.

FIG. 11 is a view for explaining the operation performed when a center part of the fine motion stage is flexed in the +Z direction.

FIG. 12A is a block diagram of an X head.

FIG. 12B is for explaining the arrangement of the X head and Y head inside a measuring arm.

FIG. 13A is an oblique view that shows a tip part of the measuring arm.

FIG. 13B is a plan view, viewed from the +Z direction, of the upper surface of the tip part of the measuring arm.

FIG. 14A is a view for explaining a method of driving a wafer during a scanning exposure.

FIG. 14B is for explaining a method of driving the wafer during stepping.

FIG. 15 is a view for explaining a wafer unloading procedure and shows the state wherein the vicinity of a chuck unit in the measurement station is viewed from a side surface.

FIG. 16 is a view for explaining a wafer unloading procedure and shows the state wherein the vicinity of the chuck unit in the measurement station is viewed from above.

FIG. 17 is a view (part 1) for explaining parallel processes performed using fine motion stages.

FIG. 18 is a view (part 1) for explaining the transfer of an immersion space (i.e., a liquid) between the fine motion stage and the movable blade.

FIG. 19 is a view (part 2) for explaining the transfer of the immersion space (i.e., the liquid) between the fine motion stage and the movable blade.

FIG. 20 is a view (part 3) for explaining the transfer of the immersion space (i.e., the liquid) between the fine motion stage and the movable blade.

FIG. 21 is a view (part 4) for explaining the transfer of the immersion space (i.e., the liquid) between the fine motion stage and the movable blade.

FIG. 22 is a view (part 2) for explaining the parallel processes performed using the fine motion stages.

FIG. 23 is a view for explaining the chucking and unchucking of a wafer by a wafer holder.

FIG. 24 is a view for explaining a first modified example of a wafer exchanging apparatus.

FIG. 25 is a view for explaining a second modified example of the wafer exchanging apparatus.

FIG. 26 is a flow chart that depicts one example of a microdevice fabricating process.

FIG. 27 depicts one example of the detailed process of step S13 described in FIG. 26.

### DESCRIPTION OF EMBODIMENTS

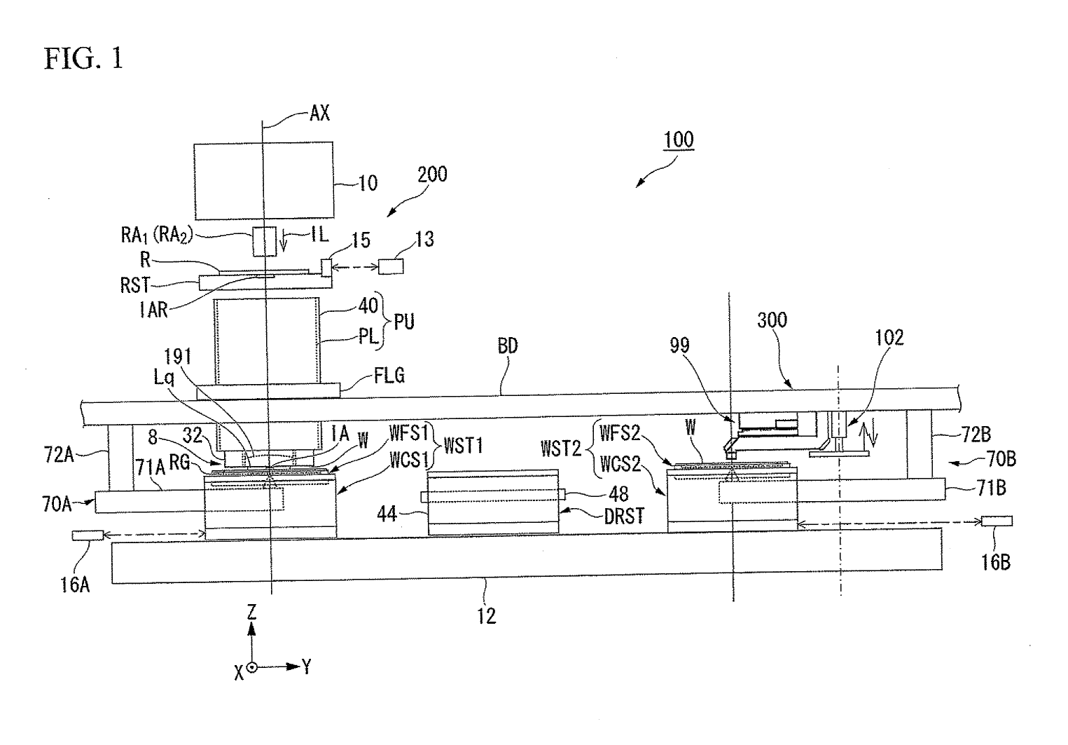

The text below explains one embodiment of the present invention, referencing FIG. 1 through FIG. 23.

FIG. 1 schematically shows the configuration of an exposure apparatus 100 according to one embodiment. The exposure apparatus 100 is a step-and-scan-type projection exposure apparatus, namely, a so-called scanner. In the present embodiment as discussed below, a projection optical system PL is provided; furthermore, in the explanation below, the directions parallel to an optical axis AX of the projection optical system. PL are the Z axial directions, the directions within a plane that is orthogonal thereto and wherein a reticle and a wafer are scanned relative to one another are the Y axial directions, the directions that are orthogonal to the Z axis and the Y axis are the X axial directions, and the rotational (i.e., tilt) directions around the X axis, the Y axis, and the Z axis are the θx, the θy, and the θz directions, respectively.

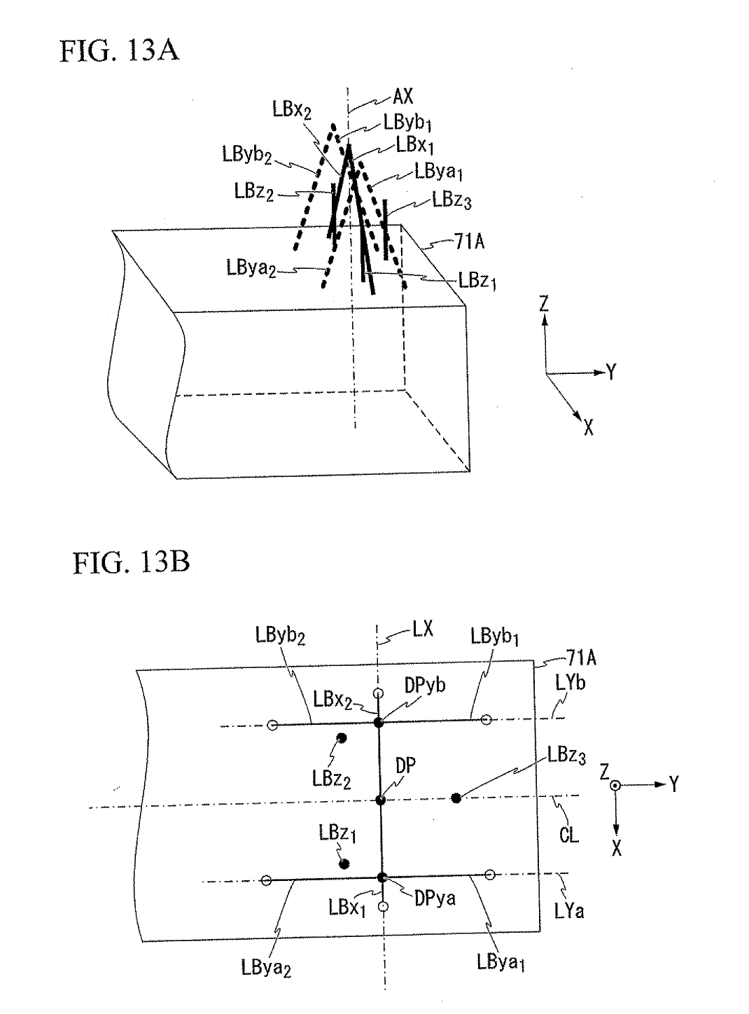

As shown in FIG. 1, the exposure apparatus 100 comprises: an exposure station 200, which is disposed on a base plate 12 in the vicinity of the −Y side end part thereof; a measurement station 300, which is disposed on the base plate 12 in the vicinity of the +Y side end part thereof; a stage apparatus ST (FIG. 13), which comprises two wafer stages WST1, WST2 and a relay stage DRST; and a control system that controls these elements. Here, the base plate 12 is supported substantially horizontally (i.e., parallel to the XY plane) on a floor surface by a vibration isolating mechanism (not shown). The base plate 12 comprises a flat plate shaped member, whose upper surface is finished to an extremely high degree of flatness, and serves as a guide surface when the three stages WST1, WST2, DRST discussed above are moved.

The exposure station 200 comprises an illumination system 10, a reticle stage RST, a projection unit PU, and a local liquid immersion apparatus 8.

As disclosed in, for example, U.S. Patent Application Publication No. 2003/0025890, the illumination system 10 comprises a light source and an illumination optical system that comprises: a luminous flux intensity uniformizing optical system, which includes an optical integrator and the like; and a reticle blind (none of which are shown). The illumination system 10 illuminates, with illumination light IL (i.e., exposure light) at a substantially uniform luminous flux intensity, a slit shaped illumination area IAR, which is defined by a reticle blind (also called a masking system), on a reticle R. Here, as one example, ArF excimer laser light (with a wavelength of 193 nm) is used as the illumination light IL.

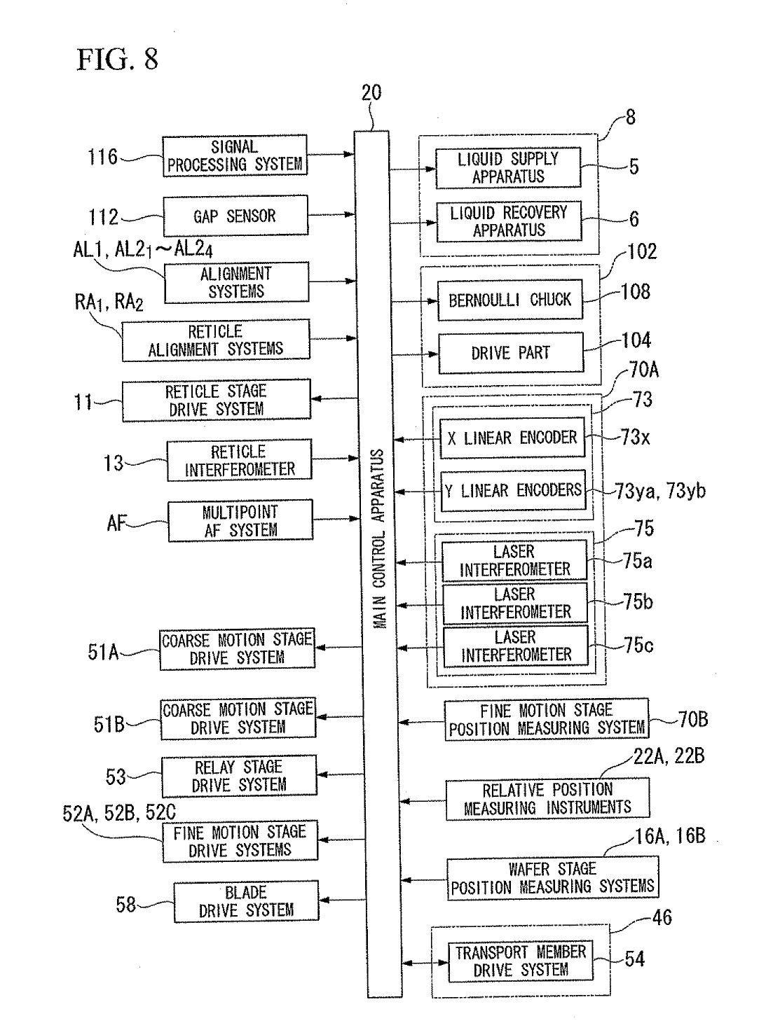

The reticle R, whose patterned surface (i.e., in FIG. 1, a lower surface) has a circuit pattern and the like formed thereon, is fixed onto the reticle stage RST by, for example, vacuum chucking. A reticle stage drive system 11 (not shown in FIG. 1; refer to FIG. 8) that comprises, for example, linear motors is capable of driving the reticle stage RST finely within an XY plane and at a prescribed scanning speed in scanning directions (i.e., in the Y axial directions, which are the lateral directions within the paper plane of FIG. 1).

A reticle laser interferometer 13 (hereinbelow, called a “reticle interferometer”) continuously detects, with a resolving power of, for example, approximately 0.25 nm, the position within the XY plane (including rotation in the θz directions) of the reticle stage RST via movable mirrors 15, which are fixed to the reticle stage RST. Measurement values of the reticle interferometer 13 are sent to a main control apparatus 20 (not shown in FIG. 1; refer to FIG. 8).

The projection unit PU is disposed below the reticle stage RST in FIG. 1. The projection unit PU is supported by a main frame BD, which is supported horizontally by a support member (not shown), via a flange part FLG, which is provided to an outer circumferential part of the projection unit PU. The projection unit PU comprises a lens barrel 40 and the projection optical system PL, which comprises a plurality of optical elements that are held inside the lens barrel 40. A dioptric optical system that is, for example, double telecentric and has a prescribed projection magnification (e.g., ¼×, ⅕×, or ⅛×) is used as the projection optical system PL. Consequently, when the illumination light IL that emerges from the illumination system 10 illuminates the illumination area IAR on the reticle R, the illumination light IL that passes through the reticle R, whose patterned surface is disposed substantially coincident with a first plane (i.e., the object plane) of the projection optical system PL, travels through the projection optical system PL (i.e., the projection unit PU) and forms a reduced image of a circuit pattern of the reticle R that lies within that illumination area IAR (i.e., a reduced image of part of the circuit pattern) on a wafer W, which is disposed on a second plane side (i.e., the image plane side) of the projection optical system PL and whose front surface is coated with a resist (i.e., a sensitive agent), in an area IA (hereinbelow, also called an “exposure area”) that is conjugate with the illumination area IAR. Furthermore, by synchronously scanning the reticle stage RST and a fine motion stage WFS1 (or WFS2), the reticle R is moved relative to the illumination area IAR (i.e., the illumination light IL) in one of the scanning directions (i.e., one of the Y axial directions) and the wafer W is moved relative to the exposure area IA (i.e., the illumination light IL) in the other scanning direction (i.e., the other Y axial direction); thereby, a single shot region (i.e., block area) on the wafer W undergoes a scanning exposure and the pattern of the reticle R is transferred to that shot region. Namely, in the present embodiment, the pattern of the reticle R is created on the wafer W by the illumination system 10 and the projection optical system PL, and that pattern is formed on the wafer W by exposing a sensitive layer (i.e., a resist layer) on the wafer W with the illumination light IL.

The local liquid immersion apparatus 8 comprises a liquid supply apparatus 5 and a liquid recovery apparatus 6 (both of which are not shown in FIG. 1; refer to FIG. 8) as well as a nozzle unit 32. As shown in FIG. 1, the nozzle unit 32 is suspended from the main frame BD, which supports the projection unit PU and the like, via a support member (not shown) such that the nozzle unit 32 surrounds a lower end part of the lens barrel 40 that holds the optical element—of the optical elements that constitute the projection optical system PL—that is most on the image plane side (i.e., the wafer W side), here, a lens 191 (hereinbelow, also called a “tip lens”). In the present embodiment, the main control apparatus 20 controls both the liquid supply apparatus 5 (refer to FIG. 8), which via the nozzle unit 32 supplies a liquid to the space between the tip lens 191 and the wafer W, and the liquid recovery apparatus 6 (refer to FIG. 8), which via the nozzle unit 32 recovers the liquid from the space between the tip lens 191 and the wafer W. At this time, the main control apparatus 20 controls the liquid supply apparatus 5 and the liquid recovery apparatus 6 such that the amount of the liquid supplied and the amount of the liquid recovered are always equal. Accordingly, a fixed amount of a liquid Lq (refer to FIG. 1) is always being replaced and held between the tip lens 191 and the wafer W. In the present embodiment, it is understood that pure water, through which ArF excimer laser light (i.e., light with a wavelength of 193 nm) transmits, is used as the abovementioned liquid.

In addition, the exposure station 200 is provided with a fine motion stage position measuring system 70A that comprises a measuring arm 71A, which is supported in a substantially cantilevered state (i.e., the vicinity of one-end part is supported) from the main frame BD via a support member 72A. However, for the sake of convenience, the fine motion stage position measuring system 70A will be explained after the fine motion stages (discussed below) are explained.

The measurement station 300 comprises: an alignment apparatus 99, which is fixed to the main frame BD in a suspended state; a chuck unit 102 (i.e., a transport apparatus); and a fine motion stage position measuring system 70B that comprises a measuring arm 71B, which is supported in a cantilevered state (i.e., the vicinity of one-end part is supported) from the main frame BD via a support member 72B. The fine motion stage position measuring system 70B is configured identically to the fine motion stage position measuring system 70A discussed above, except that it is oriented in the opposite direction.

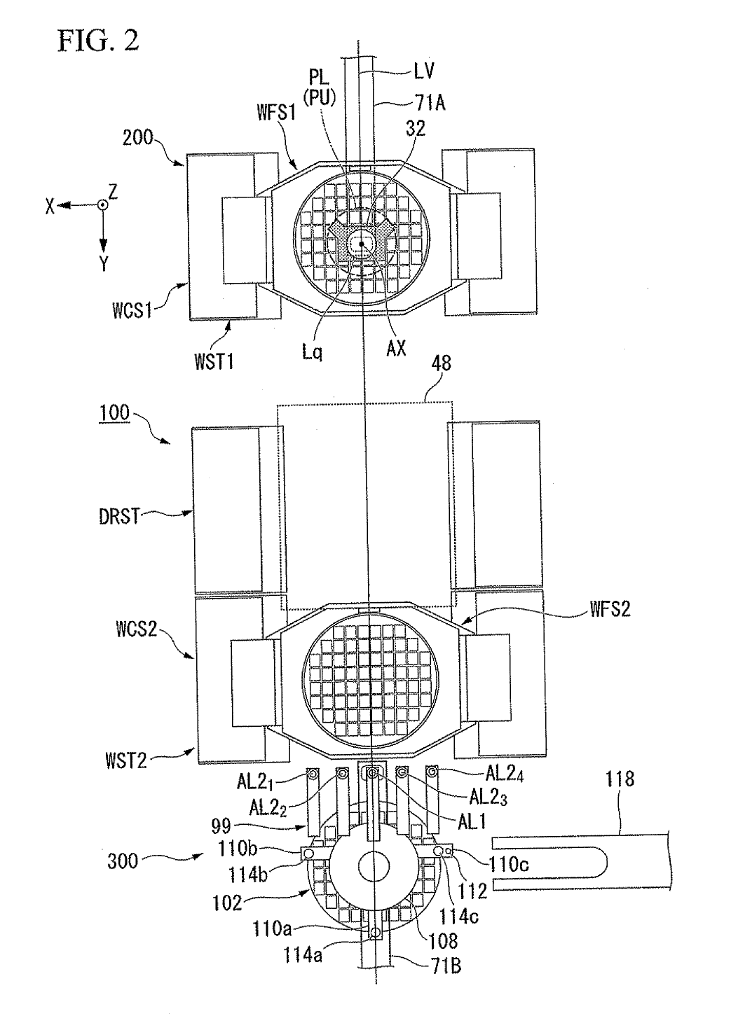

The alignment apparatus 99 comprises five alignment systems AL1, AL2₁-AL2₄ as shown in FIG. 2. In detail, as shown in FIG. 2, the primary alignment system AL1 is disposed along a straight line LV (hereinbelow, called a reference axis), which is parallel to the Y axis and passes through the center of the projection unit PU (i.e., the optical axis AX of the projection optical system PL; in the present embodiment, this center also coincides with the center of the exposure area IA discussed above), such that its center of detection is positioned spaced apart from the optical axis AX on the +Y side by a prescribed distance. The secondary alignment systems AL2₁, AL2₂ and AL2₃, AL2₄, whose centers of detection are disposed substantially symmetrically with respect to the reference axis LV, are provided on either side of the primary alignment system AL1 in the X axial directions such that the primary alignment system AL1 is interposed therebetween. Namely, the centers of detection of the five alignment systems AL1, AL2₁-AL2₄ are disposed along the X axial directions. The secondary alignment systems AL2₁, AL2₂, AL2₃, AL2₄ are held by a holding apparatus (i.e., a slider), which is capable of moving within the XY plane. Each of the alignment systems AL1, AL2₁-AL2₄ is an image processing type field image alignment (FIA) system. The signals that represent the images captured by the alignment systems AL1, AL2₁-AL2₄ are supplied to the main control apparatus 20 (refer to FIG. 8); furthermore, in FIG. 1, the five alignment systems AL1, AL2₁-AL2₄ and the holding apparatus the slider) that hold them are collectively shown as the alignment apparatus 99. Furthermore, the detailed configuration of the alignment apparatus 99 is disclosed in, for example, PCT International Publication No. WO2008/056735.

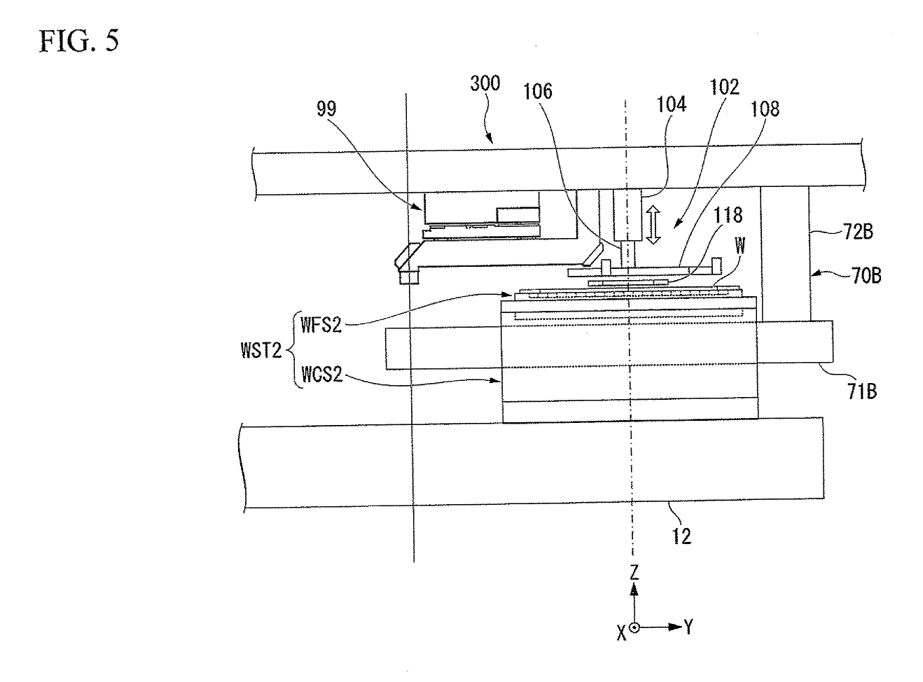

As shown in FIG. 5, the chuck unit 102 comprises: a drive part 104, which is fixed to a lower surface of the main frame BD; a shaft 106, which is driven in the vertical directions (i.e., the Z axial directions) by the drive part 104; and a Bernoulli chuck 108 (also called a “floating chuck”), which has a disc shape and is fixed to a lower end of the shaft 106.

As shown in the plan view in FIG. 2, extension parts 110a, 110b, 110c, each of which has a long, thin plate shape, are provided at three locations on an outer circumference of the Bernoulli chuck 108. A gap sensor 112 is attached to a tip of the extension part 110c and an image capturing device 114c, such as a CCD, is attached to an inner side of the gap sensor 112. In addition, image capturing devices 114a, 114b, such as CCDs, are attached to the vicinities of tip parts of the extension parts 110a, 110b, respectively.

A Bernoulli chuck is a chuck that noncontactually fixes (i.e., chucks) an object by, as is well known, making use of the Bernoulli effect to locally increase the flow velocity of a fluid (e.g., air) that is blown out. Here, the Bernoulli effect refers to the effect wherein the Bernoulli theorem (also known as the Bernoulli principle), which states that the pressure of a fluid decreases as its flow velocity increases, extends to fluid machinery and the like. In a Bernoulli chuck, the holding state (i.e., the chuck/levitation state) is determined by the weight of the object to be chucked (i.e., fixed) and by the flow velocity of the fluid blown out from the chuck. Namely, if the size of the object is known, then the size of a gap between the chuck and the object to be held during the holding process is determined by the flow velocity of the fluid blown out from the chuck. In the present embodiment, the Bernoulli chuck 108 is used in the chucking (i.e., fixing or holding) of the wafer W.

For example, a capacitance sensor is used as the gap sensor 112, which measures the distance between the circumference of the wafer W on the fine motion stage WFS2 (or WFS1) and a plate (i.e., a liquid repellent plate; discussed below) principally when the wafer W is being unloaded. The output of the gap sensor 112 is supplied to the main control apparatus 20 (refer to FIG. 5).

Viewed from the center of the Bernoulli chuck 108, the extension part 110a extends in the −Y direction. In the state wherein the center of the wafer W and the center of the Bernoulli chuck 108 are substantially coincident, the image capturing device 114a is attached to the extension part 110a at a position at which the image capturing device 114a opposes a notch (i.e., a V shaped notch; not shown) of the wafer W. In addition, in the state wherein the center of the wafer W and the center of the Bernoulli chuck 108 are substantially coincident, the remaining image capturing devices 114b, 114c are attached to the extension parts 110b, 110c, respectively, at positions at which the image capturing devices 114b, 114c oppose part of the outer circumference of the wafer W.

Captured image signals of the image capturing devices 114a-114c are sent to a signal processing system 116 (refer to FIG. 8), which uses a technique disclosed in, for example, U.S. Pat. No. 6,624,433 to detect the notch of the wafer W and the circumferential edge part on the outside thereof and to derive the positional deviation in the X axial directions and the Y axial directions as well as the rotational error (i.e., θz rotational error) of the wafer W. Furthermore, information on the positional deviations and the rotational error are supplied to the main control apparatus 20 (refer to FIG. 8).

The main control apparatus 20 (refer to FIG. 8) controls the drive part 104 of the chuck unit 102 and the Bernoulli chuck 108.

Furthermore, the exposure apparatus 100 comprises a wafer transport arm 118 that is capable of moving within an area that includes the position of the chuck unit 102 and a wafer transfer position that is spaced apart from the position of the chuck unit 102 in, for example, the +X direction (e.g., the positions on the unloading side and the loading side at which the wafer W is transferred to and from a coater-developer (not shown) connected inline to the exposure apparatus 100).

The roles and the like of the chuck unit 102 and the transport arm 118 will be discussed later.

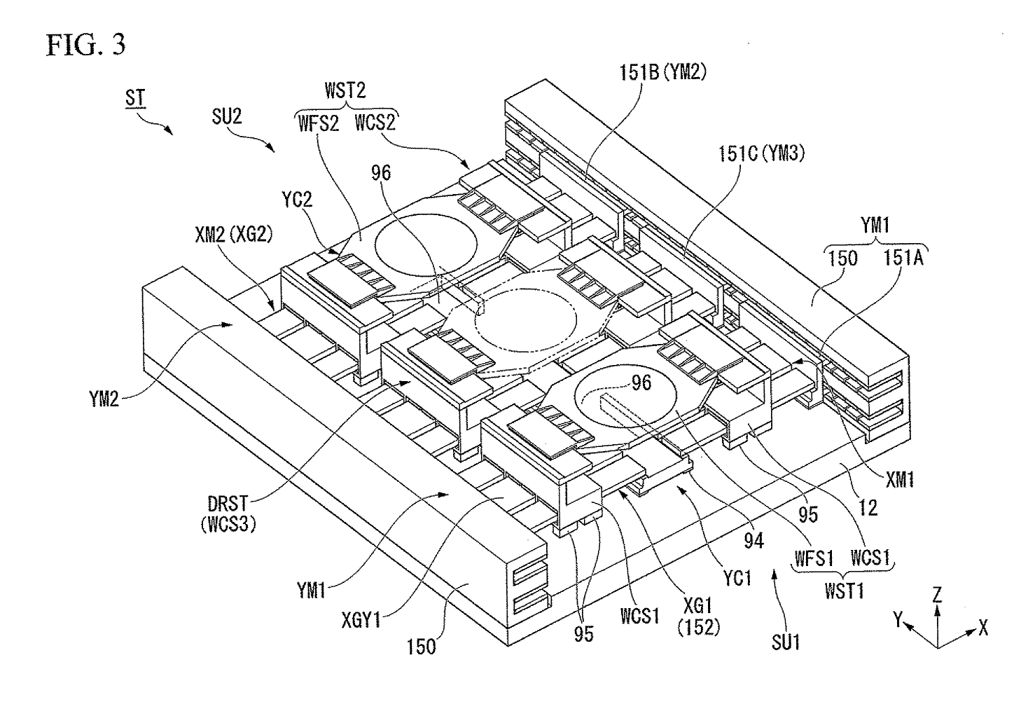

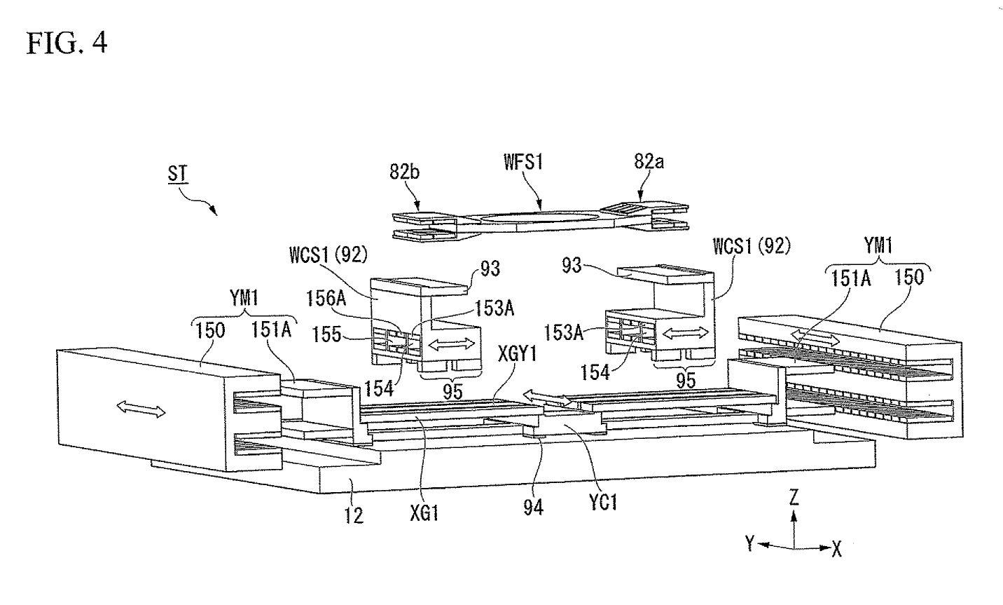

As shown in FIG. 3 and FIG. 4, the stage apparatus ST comprises: a Y coarse motion stage YC1 (i.e., a first moving body), which is driven by Y motors YM1; a Y coarse motion stage YC2 (i.e., another first moving body), which is driven by Y motors YM2; a pair of X coarse motion stages WCS1 (i.e., second moving bodies), which are independently driven by X motors XM1; a pair of X coarse motion stages WCS2 (i.e., other second moving bodies), which are independently driven by X motors XM2; the fine motion stage WFS1, which holds the wafer W and is moveably supported by the X coarse motion stages WCS1; the fine motion stage WFS2, which holds the wafer W and is moveably supported by the X coarse motion stages WCS2; and the relay stage DRST, which is driven by Y motors YM3.

The Y coarse motion stage YC1 and the X coarse motion stages WCS1 constitute a first stage unit SU1 and the Y coarse motion stage YC2 and the X coarse motion stages WCS2 constitute a second stage unit SU2.

The pair of X coarse motion stages WCS1 and the fine motion stage WFS1 constitute the wafer stage WST1 discussed above. Likewise, the pair of X coarse motion stages WCS2 and the fine motion stage WFS2 constitute the wafer stage WST2 discussed above. The fine motion stages WFS1, WFS2 are driven by fine motion stage drive systems 52A (i.e., drive apparatuses) (refer to FIG. 8) in the X, Y, Z, θx, θy, and θz directions, which correspond to six degrees of freedom, with respect to the X coarse motion stages WCS1, WCS2, respectively.

A wafer stage position measuring system 16A measures the position within the XY plane (including the rotation in the θz directions) of the wafer stage WST1 (i.e., the coarse motion stages WCS1). In addition, the fine motion stage position measuring system 70A measures the position of the fine motion stage WFS1 (or the fine motion stage WFS2), which the coarse motion stages WCS1 in the exposure station 200 support, in the directions corresponding to six degrees of freedom (i.e., the X, Y, Z, θx, θy, and θz directions). The measurement results of the wafer stage position measuring system 16A and the fine motion stage position measuring system 70A are supplied to the main control apparatus 20 (refer to FIG. 8) to control the positions of the X coarse motion stages WCS1 and the fine motion stage WFS1 (or WFS2). A wafer stage position measuring system 16B measures the position within the XY plane (including the rotation in the θz directions) of the wafer stage WST2 (i.e., the X coarse motion stages WCS2). In addition, the fine motion stage position measuring system 70B measures the position of the fine motion stage WFS2 (or WFS1), which the X coarse motion stages WCS2 in the measurement station 300 support, in the directions corresponding to six degrees of freedom (i.e., the X, Y, Z, θx, θy, and θz directions). The measurement results of the wafer stage position measuring system 16B and the fine motion stage position measuring system 70B are supplied to the main control apparatus 20 (refer to FIG. 8) to control the positions of the X coarse motion stages WCS2 and the fine motion stage WFS2 (or WFS1).

When the fine motion stage WFS1 (or WFS2) is supported by the X coarse motion stages WCS1, a relative position measuring instrument 22A (refer to FIG. 8), which is provided between the coarse motion stages WCS1 and the fine motion stage WFS1 (or WFS2), can measure the relative position of the fine motion stage WFS1 (or WFS2) and the coarse motion stages WCS1 in the X, Y, and θz directions, which correspond to three degrees of freedom. Likewise, when the fine motion stage WFS2 (or WFS1) is supported by the coarse motion stages WCS2, a relative position measuring instrument 22B (refer to FIG. 8), which is provided between the coarse motion stages WCS2 and the fine motion stage WFS2 (or WFS1), can measure the relative position of the fine motion stage WFS2 (or WFS1) and the coarse motion stages WCS2 in the X, Y, and θz directions, which correspond to three degrees of freedom.

It is possible to use as the relative position measuring instruments 22A, 22B, for example, encoders wherein gratings provided to the fine motion stages WFS1, WFS2 serve as measurement targets, each of the X coarse motion stages WCS1, WCS2 is provided with at least two heads, and the positions of the fine motion stages WFS1, WFS2 in the X axial directions, the Y axial directions, and the θz directions are measured based on the outputs of these heads. The measurement results of the relative position measuring instruments 22A, 228 are supplied to the main control apparatus 20 (refer to FIG. 8).

The relay stage DRST comprises Y coarse motion stages WCS3, which are the same as the coarse motion stages WCS1, WCS2 and are driven in the Y directions by the Y motors YM3; furthermore, the Y coarse motion stages WCS3 are levitationally supported above the base plate 12 by a plurality of noncontact bearings (e.g., air bearings; not shown) provided to the bottom surfaces of the Y coarse motion stages WCS3 and can be driven in two dimensional directions, namely, the X and Y directions, by a relay stage drive system 53 (refer to FIG. 8).

The position within the XY plane (including the rotation in the θz directions) of the relay stage DRST is measured by a position measuring system (not shown) that comprises, for example, an interferometer and/or an encoder. The measurement results of the position measuring system are supplied to the main control apparatus 20 (refer to FIG. 8) for the purpose of controlling the position of the relay stage DRST.

In addition, in the exposure apparatus 100 of the present embodiment, the pair of image processing type reticle alignment systems RA₁, RA₂ (in FIG. 1, the reticle alignment system RA₂ is hidden on the paper plane far side of the reticle alignment system RA₁) is disposed above the reticle stage RST; furthermore, each of the processing type reticle alignment systems RA₁, RA₂ comprises an image capturing device such as a CCD and uses light (in the present embodiment, the illumination light IL) of the exposure wavelength as the illumination light for alignment, as disclosed in detail in, for example, U.S. Pat. No. 5,646,413. In a state wherein a measuring plate (discussed below) is positioned on the fine motion stage WFS1 (or WFS2) directly below the projection optical system PL, the main control apparatus 20 uses the pair of reticle alignment systems RA₁, RA₂ to detect, through the projection optical system PL, a pair of first fiducial marks on the measuring plate corresponding to a projected image of a pair of reticle alignment marks (not illustrated) formed on the reticle R; thereby, the positional relationship between the center of the projection area of the pattern of the reticle R formed by the projection optical system PL and the reference position on the measuring plate, namely, the position between the centers of the two first fiducial marks, is detected. The detection signals of the reticle alignment systems RA₁, RA₂ are supplied to the main control apparatus 20 (refer to FIG. 8) via a signal processing system (not shown).

Next, the configuration of each part of the stage apparatus ST will be discussed in detail.

Furthermore, in FIG. 4, to facilitate understanding, only the configuration of the vicinity of the first stage unit SU1 is illustrated. In addition, because the configuration of the vicinity of the second stage unit SU2 is the same as that of a first stage unit SU1 and its vicinity, the following text explains only the wafer stage WST1.

The Y motors YM1 comprise stators 150, which are provided on both ends of the base plate 12 in the X directions such that they extend in the Y directions, and sliders 151A, which are provided on both ends of the Y coarse motion stage YC1 in the X directions. The Y motors YM2 comprise the abovementioned stators 150 and sliders 151B, which are provided on both ends of the Y coarse motion stage YC2 in the X directions. Namely, the Y motors YM1, YM2 are configured such that they share the stators 150. The stators 150 comprise permanent magnets, which are arrayed in the Y directions, and the sliders 151A, 151B comprise coils, which are arrayed in the Y directions. Namely, the Y motors YM1, YM2 are moving coil type linear motors that drive both the wafer stages WST1, WST2 and the Y coarse motion stages YC1, YC2 in the Y directions. Furthermore, while the above text explains an exemplary case of moving coil type linear motors, the linear motors may be moving magnet type linear motors.

In addition, aerostatic bearings (not shown), for example, air bearings, which are provided to the lower surfaces of the stators 150, levitationally support the stators 150 above the base plate 12 with a prescribed clearance. Thereby, the reaction force generated by the movement of the wafer stages WST1, WST2, the Y coarse motion stages YC1, YC2, and the like in either one of the Y directions moves the stators 150, which serve as Y countermasses in the Y directions, in the other Y direction and is thereby offset by the law of conservation of momentum.

The Y coarse motion stage YC1 comprises X guides XG1 (i.e., guide members), which are provided between the sliders 151A, 151A and extend in the X directions, and is levitationally supported above the base plate 12 by a plurality of noncontact bearings, for example, air bearings 94, that is provided to a bottom surface of the Y coarse motion stage YC1.

The X guides XG1 are provided with stators 152, which constitute the X motors XM1. As shown in FIG. 4, sliders 153A of the X motors XM1 are provided in through holes 154, wherethrough the X guides XG1 are inserted and that pass through the X coarse motion stages WCS1 in the X directions.

The two X coarse motion stages WCS1 are each levitationally supported above the base plate 12 by a plurality of noncontact bearings, for example, air bearings 95, provided to the bottom surfaces of the X coarse motion stages WCS1 and are driven in the X directions independently of one another along the X guides XG1 by the X motors XM1. The Y coarse motion stage YC1 is provided with, in addition to the X guides XG1, X guides XGY1 whereto the stators of the Y linear motors that drive the X coarse motion stages WCS1 in the Y directions are provided. Furthermore, in each of the X coarse motion stages WCS1, a slider 156A of the Y linear motor is provided in a through hole 155 (refer to FIG. 4), which passes through the X coarse motion stages WCS1 in the X directions. Furthermore, a configuration may be adopted wherein the X coarse motion stages WCS1 are supported in the Y directions by providing air bearings instead of providing the Y linear motors.

As shown in FIG. 4, a pair of sidewall parts 92 and a pair of stator parts 93, which is fixed to the upper surfaces of the sidewall parts 92, are provided to the outer side end parts in the X directions of the X coarse motion stages WCS1. As a whole, each of the coarse motion stages WCS1 has a box shape with a small height and that is open at the center part of the upper surface in the X axial directions and both side surfaces in the Y axial directions. Namely, a space is formed in each of the coarse motion stages WCS1 such that the space passes through the inner part of the coarse motion stages WCS1 in the Y axial directions.

As shown in FIG. 4, each stator part 93 of the pair of stator parts 93 comprises a plate shaped member whose outer shape is parallel to the XY plane; furthermore, each of the stator parts 93 houses a coil unit CU, which comprises a plurality of coils for driving the fine motion stage WFS1 (or WFS2). Here, the fine motion stage WFS1 and the fine motion stage WFS2 are identically configured and are similarly supported and driven noncontactually by the coarse motion stages WCS1; therefore, the text below explains the fine motion stage WFS1 only.

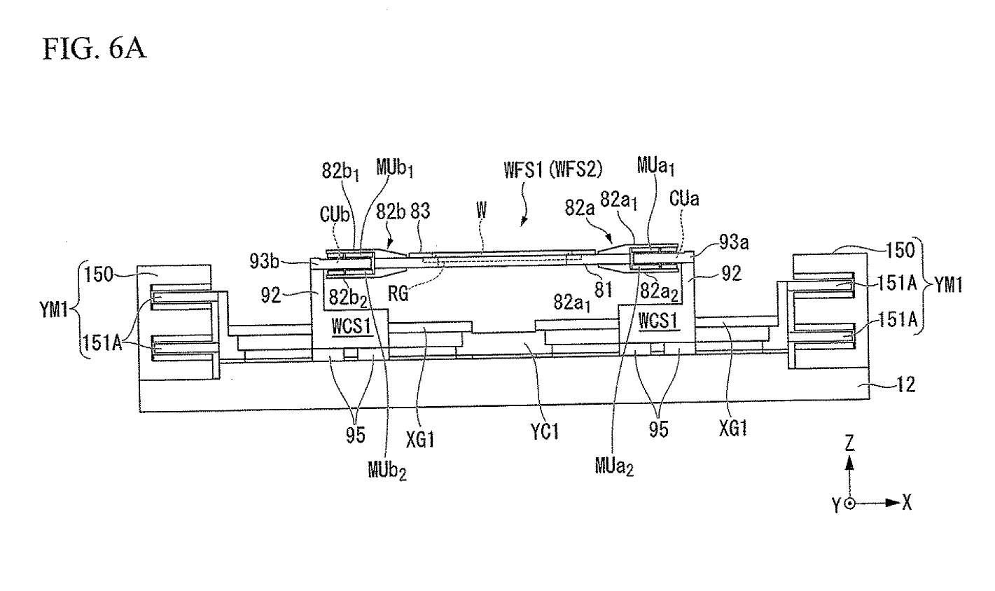

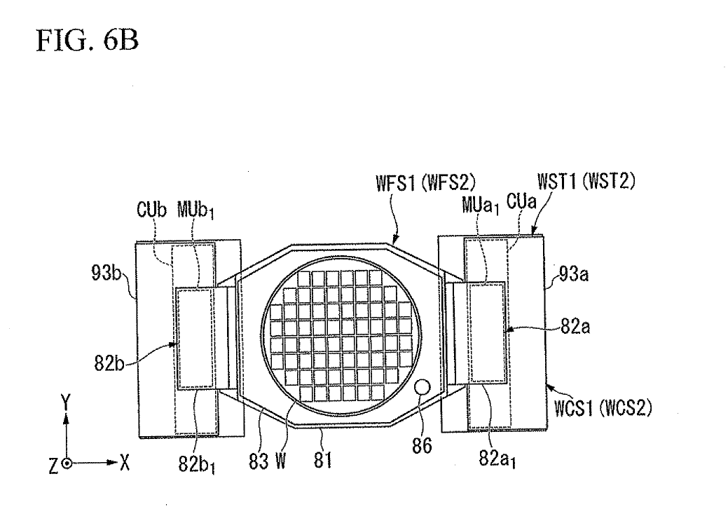

As shown in FIG. 6A and FIG. 6B, the fine motion stage WFS1 comprises a main body part 81, which consists of an octagonal plate shaped member whose longitudinal directions are oriented in the X axial directions in a plan view, and two slider parts 82a, 82b, which are fixed to one end part and an other end part of the main body part 81 in the longitudinal directions.

Because an encoder system measurement beam measurement light), which is discussed below, must be able to travel through the inner part of the main body part 81, the main body part 81 is formed from a transparent raw material wherethrough light can transmit. In addition, to reduce the effects of air turbulence on the measurement beam that passes through the inner part of the main body part 81, the main body part 81 is formed as a solid block (i.e., its interior has no space). Furthermore, the transparent raw material preferably has a low coefficient of thermal expansion; in the present embodiment, as one example, synthetic quartz (i.e., glass) is used. Furthermore, although the entire main body part 81 may be formed from the transparent material, a configuration may be adopted wherein only the portion wherethrough the measurement beam of the encoder system transmits is formed from the transparent raw material; furthermore, a configuration may be adopted wherein only the latter is formed as a solid.

A wafer holder (not shown), which holds the wafer W by vacuum chucking or the like, is provided at the center of the upper surface of the main body part 81 of the fine motion stage WFS1. Furthermore, the wafer holder may be formed integrally with the fine motion stage WFS1 and may be fixed to the main body part 81 by bonding and the like or via, for example, an electrostatic chuck mechanism or a clamp mechanism.

Furthermore, as shown in FIG. 6A and FIG. 6B, a circular opening whose circumference is larger than the wafer W (i.e., the wafer holder) is formed in the center of the upper surface of the main body part 81 on the outer side of the wafer holder (i.e., the mounting area of the wafer W), and a plate 83 (i.e., a liquid repellent plate), whose octagonal outer shape (i.e., contour) corresponds to the main body part 81, is attached to the upper surface of the main body part 81. The front surface of the plate 83 is given liquid repellency treatment (i.e., a liquid repellent surface is formed) such that it is liquid repellent with respect to the liquid Lq. The plate 83 is fixed to the upper surface of the main body part 81 such that the entire front surface (or part of the front surface) of the plate 83 is coplanar with the front surface of the wafer W. In addition, as shown in FIG. 6B, a circular opening is formed in one end part of the plate 83 and a measuring plate 86 is embedded in that opening in the state wherein the front surface of the measuring plate 86 is substantially coplanar with the front surface of the plate 83, namely, the front surface of the wafer W. At least a pair of the first fiducial marks discussed above and a second fiducial mark, which is detected by a wafer alignment system, are formed in the front surface of the measuring plate 86 (note that none of the first and second fiducial marks are shown).

As shown in FIG. 6A, a two-dimensional grating RG (hereinbelow, simply called a “grating”) that serves as a measurement surface is disposed horizontally (i.e., parallel to the front surface of the wafer W) on the upper surface of the main body part 81 in an area whose circumference is larger than the wafer W. The grating RG comprises a reflective diffraction grating whose directions of periodicity are oriented in the X axial directions (i.e., an X diffraction grating) and a reflective diffraction grating whose directions of periodicity are oriented in the Y axial directions (i.e., a Y diffraction grating).

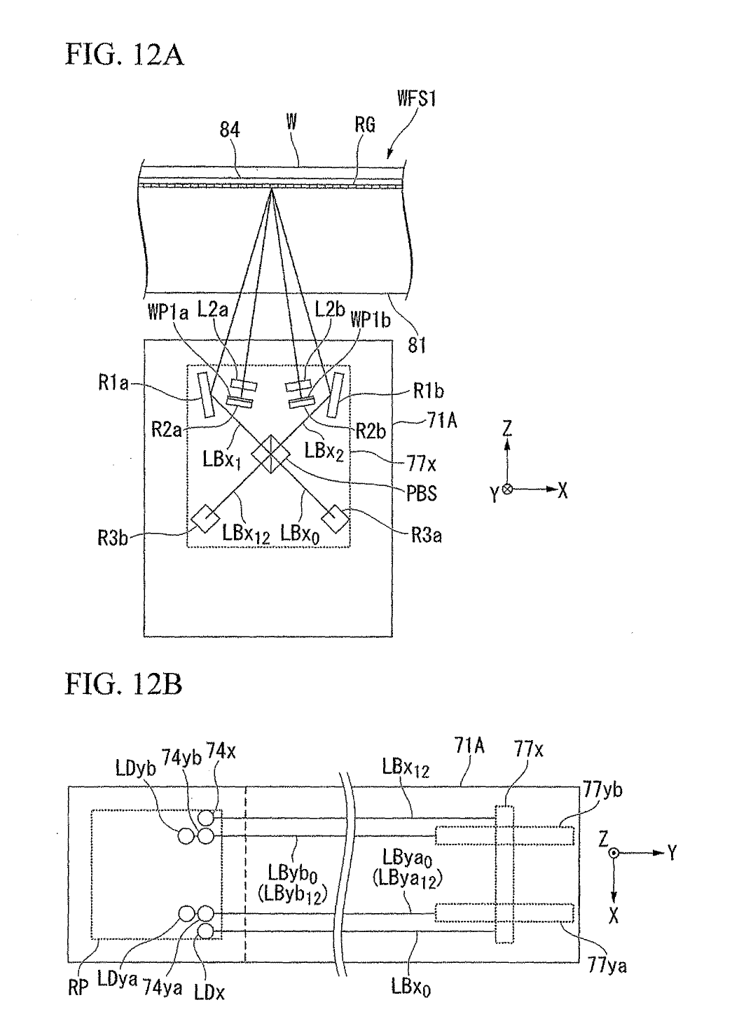

The upper surface of the grating RG is covered by a protective member, for example, a cover glass 84 (not shown in FIG. 6A, refer to FIG. 12A). In the present embodiment, the electrostatic chucking mechanism (discussed above), which chucks the wafer holder, is provided to the upper surface of the cover glass 84. Furthermore, in the present embodiment, the cover glass 84 is provided such that it covers substantially the entire upper surface of the main body part 81, but the cover glass 84 may be provided such that it covers only the part of the upper surface of the main body part 81 that includes the grating RG. In addition, the protective member (i.e., the cover glass 84) may be formed from a raw material identical to that of the main body part 81, but the present invention is not limited thereto; for example, the protective member may be formed from, for example, a metal or a ceramic material, or a configuration may be adopted wherein the protective member is formed as a thin film or the like.

As can be understood also from FIG. 6A, the main body part 81 is, as a whole, an octagonal plate shaped member wherein overhanging parts that protrude toward the outer side from both end parts in the longitudinal directions are formed, and a recessed part is formed in the bottom surface of the main body part 81 at the portion that opposes the grating RG. The main body part 81 is formed as a plate whose center area at which the grating RG is disposed has a substantially uniform thickness.

As shown in FIG. 6A and FIG. 6B, the slider part 82a comprises two plate shaped members 82a₁, 82a₂, which are rectangular in a plan view and whose size in the Y axial directions (i.e., length) and size in the X axial directions (i.e., width) are both smaller (by about one half) than those of the stator part 93a. The plate shaped members 82a₁, 82a₂ are fixed to the +X side end part of the main body part 81 in the state wherein they are spaced apart from one another by a prescribed distance in the Z axial directions (i.e., the vertical directions) and such that they are parallel to the XY plane. The −X side end part of the stator part 93a is noncontactually inserted between the two plate shaped members 82a₁, 82a₂. The plate shaped members 82a₁, 82a₂ respectively house magnet units MUa₁, MUa₂ (discussed below).

The slider part 82b comprises two plate shaped members 82b₁, 82b₂, which are maintained at a prescribed spacing in the Z axial directions (i.e., the vertical directions), and is bilaterally symmetric with and configured identically to the slider part 82a. A +X side end part of a stator part 93b is inserted noncontactually between the two plate shaped members 82b₁, 82b₂. The plate shaped members 82b₁, 82b₂ respectively house magnet units MUb₁, MUb₂, which are respectively configured identically to the magnet units MUa₁, MUa₂.

Here, as discussed above, both side surfaces of the coarse motion stages WCS1 in the Y axial directions are open; therefore, when the fine motion stage WFS1 is mounted to the coarse motion stages WCS1, the fine motion stage WFS1 should be positioned in the Z axial directions such that the stator parts 93a, 93b are positioned between the plate shaped members 82a₁, 82a₂ and 82b₁, 82b₂, respectively; subsequently, the fine motion stage WFS1 should be moved (i.e., slid) in the Y axial directions.

A fine motion stage drive system 52A comprises: the pair of magnet units MUa₁, MUa₂, which are provided by the slider part 82a (discussed above); a coil unit CUa, which is provided by the stator part 93a; the pair of magnet units MUb₁, MUb₂, which is provided by the slider part 82b (discussed above); and a coil unit CUb, which is provided by the stator part 93b.

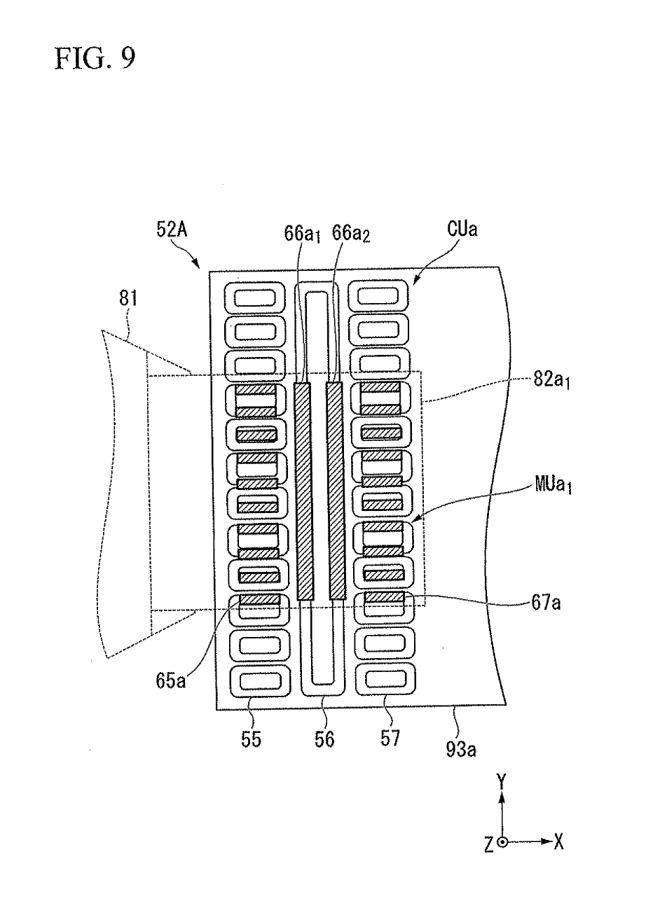

This will now be discussed in more detail. As can be understood from FIG. 9, a plurality of YZ coils 55, 57 (here, 12 each; hereinbelow, abbreviated as “coils” where appropriate), which are oblong in a plan view, are disposed equispaced in the Y axial directions inside the stator part 93a such that they constitute a two column coil array. The two columns of the coil array are disposed with a prescribed spacing between them in the X axial directions. Each of the YZ coils 55 comprises an upper part winding and a lower part winding (not shown), which are rectangular in a plan view and disposed such that they overlap in the vertical directions (i.e., the Z axial directions). In addition, one X coil 56 (hereinbelow, abbreviated as “coil” where appropriate), which in a plan view is a long, thin oblong whose longitudinal directions are oriented in the Y axial directions, is disposed inside the stator part 93a and between the columns of the two-column coil array discussed above. In this case, each of the columns of the two-column coil array and the X coil 56 are disposed equispaced in the X axial directions. Together, the two-column coil array and the X coil 56 constitute the coil unit CUa.

Furthermore, the following text explains the stator part 93a and the slider part 82a, which have the coil unit CUa and the magnet units MUa₁, MUa₂, respectively, referencing FIG. 9; the other stator and slider, that is, the stator part 93b and the slider part 82b, are similarly configured and function in the same manner.

As can be understood by referencing FIG. 9, a plurality of permanent magnets 65a, 67a (herein, 10 of each), which are oblong in a plan view and whose longitudinal directions are oriented in the X axial directions, are disposed equispaced in the Y axial directions inside the +Z side plate shaped member 82a₁, which constitutes part of the slider part 82a, and thereby constitute a two-column magnet array. The two columns of the magnet array are disposed spaced apart from one another by a prescribed spacing in the X axial directions and such that they oppose the coils 55, 57. In addition, two permanent magnets 66a₁, 66a₂, which are disposed spaced apart in the X axial directions and whose longitudinal directions are oriented in the Y axial directions, are disposed inside the plate shaped member 82a₁ between the columns of the two-column magnet array discussed above such that they oppose the coil 56.

The permanent magnets 65a, are arrayed such that their directions of polarity alternate. The magnet column that comprises the plurality of the permanent magnets 67a is configured identically to the magnet column that comprises the plurality of the permanent magnets 65a. In addition, the permanent magnets 66a₁, 66a₂ are disposed such that their polarities are the opposite of one another. The plurality of the permanent magnets 65a, 67a and 66a₁, 66a₂ constitutes the magnet unit MUa₁.

As in the plate shaped member 82a₁ discussed above, permanent magnets also are disposed inside the plate shaped member 82a₂ on the −Z side, and these permanent magnets constitute the magnet unit MUa₂.

Here, the positional relationship in the Y axial directions between the permanent magnets 65a, which are disposed adjacently in the Y axial directions, and the YZ coils 55 (i.e., the relationship of the spacings between them) is set such that, when the two adjacent permanent magnets 65a (called “first and second permanent magnets” for the sake of convenience) oppose the winding parts of the YZ coils 55 (called “first YZ coils” for the sake of convenience), the third permanent magnet 65a adjacent to the second permanent magnet 65a does not oppose the winding part of the second YZ coil 55 adjacent to the first YZ coil 55 discussed above (i.e., the positional relationship is set either such that the third permanent magnet 65a opposes the hollow part at the center of the coil or such that it opposes the core, for example, the iron core, around which the coil is wound). In such a case, the fourth permanent magnet 65a, which is adjacent to the third permanent magnet 65a, and the fifth permanent magnet 65a each oppose the winding part of the third YZ coil 55, which is adjacent to the second YZ coil 55. This likewise applies to the spacing in the Y axial directions between the permanent magnets 67a and the two column permanent magnet array inside the plate shaped member 82a₂ on the −Z side.

Because the present embodiment adopts the arrangement of the coils and permanent magnets as discussed above, the main control apparatus 20 can drive the fine motion stage WFS1 in the Y axial directions by supplying an electric current to every other coil of the plurality of the YZ coils 55, 57 arrayed in the Y axial directions. In addition, in parallel therewith, the main control apparatus 20 can levitate the fine motion stage WFS1 above the coarse motion stages WCS1 through generating driving forces in the Z axial directions that are separate from the driving forces in the Y axial directions by supplying electric currents to coils of the YZ coils 55, 57 that are not used to drive the fine motion stage WFS1 in the Y axial directions. Furthermore, by sequentially switching, in accordance with the position of the fine motion stage WFS1 in the Y axial directions, which of the coils are supplied with electric current, the main control apparatus 20 drives the fine motion stage WFS1 in the Y axial directions while maintaining the state wherein the fine motion stage WFS1 is levitated above the coarse motion stages WCS1, namely, a noneontactual state. In addition, in the state wherein the fine motion stage WFS1 is levitated above the coarse motion stages WCS1, the main control apparatus 20 can also drive the fine motion stage WFS1 independently in the X axial directions in addition to the Y axial directions.

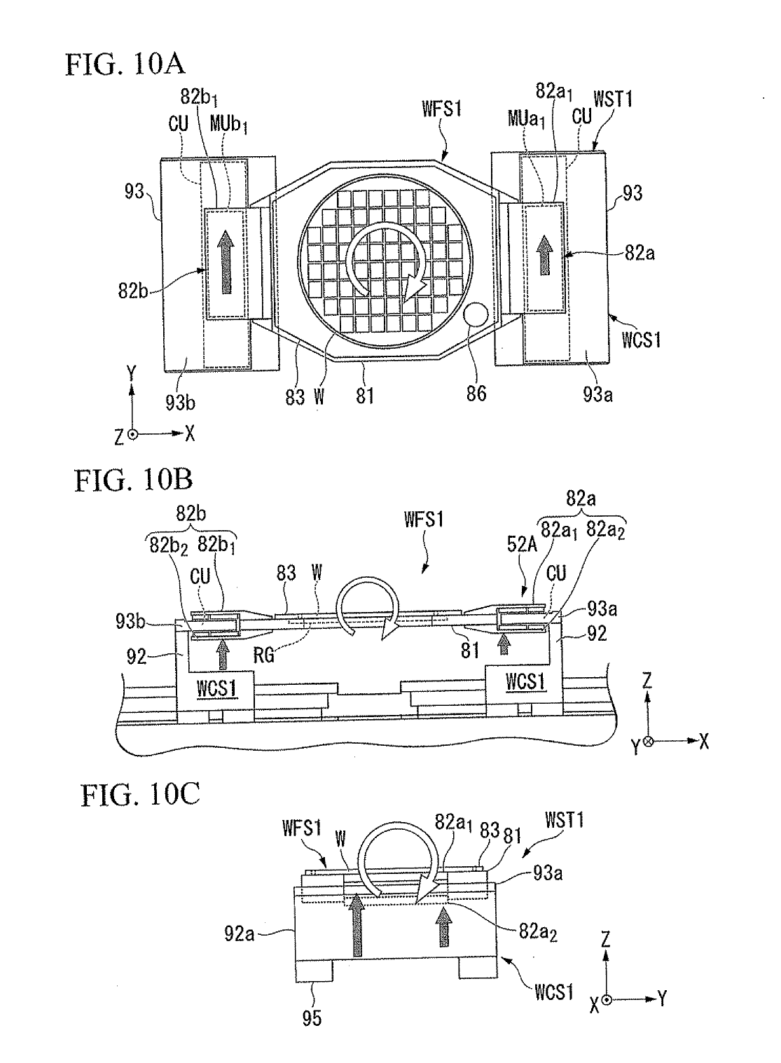

In addition, as shown in, for example, FIG. 10A, the main control apparatus 20 can rotate the fine motion stage WFS1 around the Z axis (i.e., can perform θz rotation; refer to the outlined arrow in FIG. 10A) by causing driving forces (i.e., thrusts) in the Y axial directions of differing magnitudes to act on the slider part 82a and the slider part 82b (refer to the solid arrows in FIG. 10A). Furthermore, the fine motion stage WFS1 can be rotated counterclockwise around the Z axis by, in a method the reverse of that described in FIG. 10A, making the driving force that acts on the slider part 82a on the +X side larger than the driving force that acts on the slider part 82a on the −X side.

In addition, as shown in FIG. 10B, the main control apparatus 20 can rotate the fine motion stage WFS1 around the Y axis (i.e., can perform θy drive; refer to the outlined arrow in FIG. 10B) by causing levitational forces of differing magnitudes to act on the slider part 82a and the slider part 82b (refer to the solid arrows in FIG. 10B). Furthermore, the fine motion stage WFS1 can be rotated counterclockwise around the Y axis by, in a method the reverse of that described in FIG. 10B, making the levitational forces that act on the slider part 82a greater than the levitational forces that act on the slider part 82b.

Furthermore, as shown in, for example, FIG. 10C, the main control apparatus 20 can rotate the fine motion stage WFS1 around the X axis (i.e., can perform θx drive (θx rotation); refer to the outlined arrow in FIG. 10C) by causing levitational forces of differing magnitudes to act on the +Y side and the −Y side slider parts 82a, 82b in the Y axial directions (refer to the solid arrows in FIG. 10C). Furthermore, the fine motion stage WFS1 can be rotated counterclockwise around the X axis by, in a method the reverse of that described in FIG. 10C, making the levitational force that acts on the −Y side portion smaller than the levitational force that acts on the +Y side portion of the slider parts 82a (and 82b).

As can be understood from the explanation above, in the present embodiment, the fine motion stage drive system 52A can levitationally support the fine motion stage WFS1 in a noncontactual state above the coarse motion stages WCS1 and can drive the coarse motion stages WCS1 noncontactually in the X, Y, and Z axial directions. In addition, the main control apparatus 20 can rotate the fine motion stage WFS1 around the Z axis (i.e., can perform θz rotation; refer to the outlined arrow in FIG. 10A) by causing driving forces (i.e., thrusts) in the Y axial directions of differing magnitudes to act on the slider part 82a and the slider part 82b (refer to the solid arrows in FIG. 10A). In addition, the main control apparatus 20 can rotate the fine motion stage WFS1 around the Y axis (i.e., can perform θy drive (θy rotation); refer to the outlined arrow in FIG. 10B) by causing levitational forces of differing magnitudes to act on the slider part 82a and the slider part 82b (refer to the solid arrows in FIG. 10B). Furthermore, as shown in, for example, FIG. 10C, the main control apparatus 20 can rotate the fine motion stage WFS1 around the X axis (i.e., can perform θx drive; refer to the outlined arrow in FIG. 10C) by causing levitational forces of differing magnitudes to act on the +Y side slider part 82a and the −Y side slider part 82b of the fine motion stage WFS1 (refer to the solid arrows in FIG. 10C).

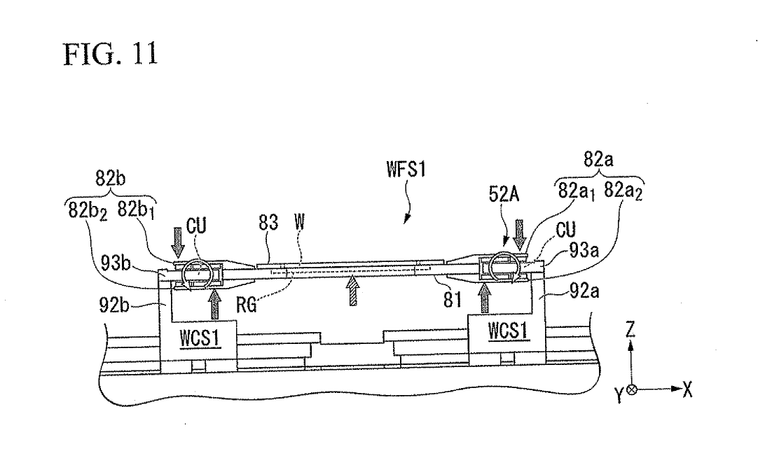

In addition, in the present embodiment, when levitational forces are caused to act on the fine motion stage WFS1, the main control apparatus 20 can cause a rotational force around the Y axis to act on the slider part 82a (refer to the outlined arrow in FIG. 11) at the same time that levitational forces act on the slider part 82a (refer to the solid arrow in FIG. 11), as shown in, for example, FIG. 11, by supplying electric currents in opposite directions to the two columns of YZ coils 55, 57 disposed inside the stator part 93a. Similarly, when levitational forces are caused to act on the fine motion stage WFS1, the main control apparatus 20 can cause a rotational force around the Y axis to act on the slider part 82a at the same time that levitational forces act on the slider part 82b by supplying electric currents in opposite directions to the two columns of YZ coils 55, 57 disposed inside the stator part 93b.

In addition, the main control apparatus 20 can flex in the +Z direction or the −Z direction (refer to the hatched arrow in FIG. 11) the center part of the fine motion stage WFS1 by causing rotational forces (i.e., θy directional forces) around the Y axis to act on the slider parts 82a, 82b in opposite directions. Accordingly, as shown in FIG. 11, it can ensure a degree of parallelism between the front surface of the wafer W and the XY plane (i.e., the horizontal plane) by flexing in the +Z direction (i.e., by causing to protrude) the center part of the fine motion stage WFS1 in the X axial directions and thereby canceling the flexure in the X axial directions of an intermediate portion of the fine motion stage WFS1 (i.e., the main body part 81) owing to the self weights of the wafer W and the main body part 81. Thereby, this aspect is particularly effective when, for example, the size of the wafer W or of the fine motion stage WFS1 is increased. Furthermore, FIG. 11 shows an example wherein the fine motion stage WFS1 is flexed in the +Z direction (i.e., so as to form a convex shape), but it is also possible to flex the fine motion stage WFS1 in the opposite direction (i.e., so as to form a concave shape) by controlling the directions of the electric currents supplied to the coils.

In the exposure apparatus 100 of the present embodiment, when a step-and-scan type exposure operation is being performed on the wafer W, the main control apparatus 20 uses an encoder system 73 (refer to FIG. 8) of the fine motion stage position measuring system 70A (discussed below) to measure the position within the XY plane (including the position in the θz directions) of the fine motion stage WFS1. The positional information of the fine motion stage WFS1 is sent to the main control apparatus 20, which, based thereon, controls the position of the fine motion stage WFS1.

In contrast, when the wafer stage WST1 (i.e., the fine motion stage WFS1) is positioned outside of the measurement area of the fine motion stage position measuring system 70A, the main control apparatus 20 uses the wafer stage position measuring system 16A (refer to FIG. 1 and FIG. 8) to measure the position of the wafer stage WST1 (and the fine motion stage WFS1). As shown in FIG. 1, the wafer stage position measuring system 16A comprises laser interferometers, which radiate length measuring beams to reflective surfaces on the side surfaces of the coarse motion stages WCS1 and measure the position within the XY plane (including the rotation in the θz directions) of the wafer stage WST1. Furthermore, instead of using the wafer stage position measuring system 16A discussed above to measure the position within the XY plane of the wafer stage WST1, some other measuring apparatus, for example, an encoder system, may be used. In such a case, for example, a two dimensional scale can be disposed on the upper surface of the base plate 12, and an encoder head can be provided to each of the bottom surfaces of the coarse motion stages WCS1.

As discussed above, the fine motion stage WFS2 is configured identically to the fine motion stage WFS1 discussed above; furthermore, the coarse motion stages WCS1 can noncontactually support the fine motion stage WFS2 instead of the fine motion stage WFS1. In such a case, the wafer stage WST1 would comprise the coarse motion stages WCS1 and the fine motion stage WFS2 supported by the coarse motion stages WCS1, and the fine motion stage drive system 52A would comprise the pairs of slider parts (i.e., the pairs of magnet units MUa₁, MUa₂ and MUb₁, MUb₂) provided by the fine motion stage WFS2 and the pair of stator parts 93a, 93b (i.e., the coil units CUa, CUb) of the coarse motion stages WCS1. Furthermore, the fine motion stage drive system 52A would drive the fine motion stage WFS2 noncontactually with respect to the coarse motion stages WCS1 in the directions corresponding to six degrees of freedom.

In addition, each of the fine motion stages WFS2, WFS1 can be supported noncontactually by the coarse motion stages WCS2; furthermore, the wafer stage WST2 comprises the coarse motion stages WCS2 and the fine motion stage WFS2 or WFS1 supported by the coarse motion stages WCS2. In this case, a fine motion stage drive system 52B (refer to FIG. 8) would comprise the pairs of slider parts (i.e., the pairs of magnet units MUa₁, MUa₂ and MUb₁, MUb₂) provided by the fine motion stage WFS2 or WFS1 and the pair of stator parts 93a, 93b (i.e., the coil units CUa, CUb) of the coarse motion stages WCS2. Furthermore, the fine motion stage drive system 52B would drive the fine motion stage WFS2 or WFS1 noncontactually with respect to the coarse motion stages WCS2 in the directions corresponding to six degrees of freedom.

Returning to FIG. 1, the relay stage DRST comprises: a stage main body 44, which is configured identically to the coarse motion stages WCS1, WCS2; and a transport apparatus 46 (refer to FIG. 8), which is provided inside the stage main body 44. However, the coarse motion stages WCS3 in the relay stage DRST are not configured such that they can separate from one another.

Accordingly, as in the coarse motion stages WCS1, WCS2, the stage main body 44 can noncontactually support (i.e., hold) the fine motion stage WFS1 or WFS2; furthermore, a fine motion stage drive system 52C (refer to FIG. 8) can drive the fine motion stage supported by the relay stage DRST in directions corresponding to six degrees of freedom (i.e., the X, Y, Z, θx, θy, and θz directions) with respect to the relay stage DRST. However, the fine motion stage should be able to slide in at least the Y axial directions with respect to the relay stage DRST.

The transport apparatus 46 comprises: a transport member main body, which is capable of reciprocal motion with a prescribed stroke in the Y axial directions along both sidewalls of the stage main body 44 of the relay stage DRST in the X axial directions and is capable of vertical motion with a prescribed stroke in the Z axial directions; a transport member 48, which holds the fine motion stage WFS1 or WFS2 and is a movable member that can move relative to the transport member main body in the Y axial directions; and a transport member drive system 54 (refer to FIG. 8), which can individually drive the transport member main body and the movable member that constitute the transport member 48.

The following text explains the configuration of the fine motion stage position measuring system 70A (refer to FIG. 8), which is used to measure the position of the fine motion stage WFS1 or WFS2 (which constitutes the wafer stage WST1) held moveably by the coarse motion stages WCS1 in the exposure station 200. Here, the case wherein the fine motion stage position measuring system 70A measures the position of the fine motion stage WFS1 will be explained.

As shown in FIG. 1, the fine motion stage position measuring system 70A comprises the measuring arm 71A, which is inserted in the space inside each of the coarse motion stages WCS1 in the state wherein the wafer stage WST1 is disposed below the projection optical system PL. The measuring arm 71A is supported in a cantilevered state by the main frame BD via the support member 72A (i.e., the vicinity of one-end part is supported).

The measuring arm 71A is a square columnar shaped member (i.e., a rectangular parallelepipedic member) whose longitudinal directions are oriented in the Y axial directions and whose longitudinal oblong cross section is such that the size in the height directions (i.e., the Z axial directions) is greater than the size in the width directions (i.e., the X axial directions); furthermore, the measuring arm 71A is formed from the identical raw material wherethrough the light transmits, for example, by laminating a plurality of glass members together. The measuring arm 71A is formed as a solid, excepting the portion wherein the encoder head (i.e., the optical system) is housed (discussed below). As discussed above, a tip part of the measuring arm 71A is inserted in the spaces of the coarse motion stages WCS1 in the state wherein the wafer stage WST1 is disposed below the projection optical system PL; furthermore, as shown in FIG. 1, the upper surface of the measuring arm 71A opposes the lower surface of the fine motion stage WFS1 (more accurately, the lower surface of the main body part 81; not shown in FIG. 1; refer to FIG. 6A and the like). The upper surface of the measuring arm 71A is disposed substantially parallel to the lower surface of the fine motion stage WFS1 in the state wherein a prescribed clearance, for example, approximately several millimeters, is formed between the upper surface of the measuring arm 71A and the lower surface of the fine motion stage WFS1.

As shown in FIG. 8, the fine motion stage position measuring system 70A comprises the encoder system 73 and a laser interferometer system 75. The encoder system 73 comprises an X linear encoder 73x, which measures the position of the fine motion stage WFS1 in the X axial directions, and a pair of Y linear encoders 73ya, 73yb, which measures the position of the fine motion stage WFS1 in the Y axial directions. The encoder system 73 uses diffraction interference type heads with a configuration identical to that of the encoder head (hereinbelow, abbreviated as “head” where appropriate) disclosed in, for example, U.S. Pat. No. 7,238,931 and U.S. Patent Application Publication No. 2007/288121. However, in the head of the present embodiment, the light source and a light receiving system (including a photodetector) are disposed outside of the measuring arm 71A (as discussed below), and only the optical system is disposed inside the measuring arm 71A, namely, opposing the grating RG. Hereinbelow, the optical system disposed inside the measuring arm 71A is called a head where appropriate.

The encoder system 73 uses one X head 77x (refer to FIG. 12A and FIG. 12B) to measure the position of the fine motion stage WFS1 in the X axial directions, and uses a pair of Y heads 77ya, 77yb (refer to FIG. 12B) to measure the position of the fine motion stage WFS1 in the Y axial directions. Namely, the X linear encoder 73x (discussed above) comprises the X head 77x that uses the X diffraction grating of the grating RG to measure the position of the fine motion stage WFS1 in the X axial directions, and the pair of Y linear encoders 73ya, 73yb comprises the pair of Y heads 77ya, 77yb that uses the Y diffraction grating of the grating RU to measure the position of the fine motion stage WFS1 in the Y axial directions.

Here, the configuration of the three heads 77x, 77ya, 77yb that constitute the encoder system 73 will be explained. FIG. 12A shows a schematic configuration of the X head 77x, which represents all three of the heads 77x, 77ya, 77yb. In addition, FIG. 12B shows the arrangement of the X head 77x and the Y heads 77ya, 77yb inside the measuring arm 71A.

As shown in FIG. 12A, the X head 77x comprises a polarizing beam splitter PBS, a pair of reflective mirrors R1a, R1b, a pair of lenses L2a, L2b, a pair of quarter wave plates WP1a, WP1b (hereinbelow, denoted as λ/4 plates), a pair of reflective mirrors R2a, R2b, and a pair of reflective mirrors R3a, R3b; furthermore, these optical elements are disposed with prescribed positional relationships. The optical systems of the Y heads 77ya, 77yb also have the same configuration. As shown in FIG. 12A and FIG. 12B, the X head 77x and the Y heads 77ya, 77yb are each unitized and fixed inside the measuring arm 71A.

As shown in FIG. 12B, in the X head 77x (i.e., the X linear encoder 73x), a light source LDx, which is provided to the upper surface of the −Y side end part of the measuring arm 71A (or there above), emits in the −Z direction a laser beam LBx₀, the laser beam LBx₀ transits a reflective surface RP, which is provided to part of the measuring arm 71A such that the reflective surface RP is tilted at a 45° angle with respect to the XY plane, and the optical path of the laser beam LBx₀ is thereby folded in a direction parallel to the Y axial directions. The laser beam LBx₀ advances parallel to the Y axial directions through the solid portion inside the measuring arm 71A and reaches the reflective mirror R3a (refer to FIG. 12A). Furthermore, the reflective mirror R3a folds the optical path of the laser beam LBx₀, and the laser beam LBx₀ thereby impinges the polarizing beam splitter PBS. The polarizing beam splitter PBS polarizes and splits the laser beam LBx₀, which becomes two measurement beams LBx₁, LBx₂. The measurement beam. LBx₁, which transmits through the polarizing beam splitter PBS, reaches the grating RG, which is formed in the fine motion stage WFS1, via the reflective mirror R1a; furthermore, the measurement beam LBx₂, which is reflected by the polarizing beam splitter PBS, reaches the grating RG via the reflective mirror R1b. Furthermore, “polarization splitting” herein means the splitting of the incident beam into a P polarized light component and an S polarized light component.

Diffraction beams of a prescribed order (e.g., first order diffraction beams), which are generated by the grating RG as a result of the radiation of the beams LBx₁, LBx₂, transit the lenses L2a, L2b, are converted to circularly polarized beams by the λ/4 plates WP1a, WP1b, are subsequently reflected by the reflective mirrors R2a, R2b, pass once again through the λ/4 plates WP1a, WP1b, and reach the polarizing beam splitter PBS by tracing the same optical path as the forward path, only in reverse.

The polarization directions of each of the two first order diffraction beams that reach the polarizing beam splitter PBS are rotated by 90° with respect to the original directions. Consequently, the first order diffraction beams of the measurement beams LBx₁, LBx₂ are combined coaxially as a combined beam LBx₁₂. The reflective mirror R3b folds the optical path of the combined beam LBx₁₂ such that it is parallel to the Y axis, after which the combined beam LBx₁₂ travels parallel to the Y axis inside the measuring arm 71A, transits the reflective surface RP (discussed above), and is sent to an X light receiving system 74x, which is provided to the upper surface of the −Y side end part of the measuring arm 71A (or there above), as shown in FIG. 12B.

In the X light receiving system 74x, the first order diffraction beams of the measurement beams LBx₁, LBx₂, which were combined into the combined beam LBx₁₂, are aligned in their polarization directions by a polarizer (i.e., an analyzer), which is not shown, and therefore interfere with one another to form an interfered beam, which is detected by the photodetector (not shown) and then converted to an electrical signal that corresponds to the intensity of the interfered beam. Here, when the fine motion stage WFS1 moves in either of the measurement directions (in this case, the X axial directions), the phase difference between the two beams changes, and thereby the intensity of the interfered beam changes. These changes in the intensity of the interfered beam are supplied to the main control apparatus 20 (refer to FIG. 8) as the positional information in the X axial directions of the fine motion stage WFS1.

As shown in FIG. 12B, laser beams LBya₀, LByb₀, which are respectively emitted from light sources LDya, LDyb and whose optical paths are folded by 90° by the reflective surface RP (discussed above) such that the beams travel parallel to the Y axis, enter the Y heads 77ya, 77yb and, as was discussed above, combined beams LBya₁₂, LByb₁₂ of the first order diffraction beams diffracted by the grating RG (i.e., the Y diffraction grating) from the measurement beams that were polarized and split by the polarizing beam splitters are output from the Y heads 77ya, 77yb, respectively, and then return to Y light receiving systems 74ya, 74yb. Here, the laser beams LBya₀, LByb₀, which were emitted from the light sources LDya, LDyb, and the combined beams LBya₁₂, LByb₁₂, which return to the Y light receiving systems 74ya, 74yb, travel with overlapping optical paths in the directions perpendicular to the paper plane in FIG. 12B. In addition, as discussed above, inside the Y heads 77ya, 77yb, the optical paths of the laser beams LBya₀, LByb₀ radiated from the light sources LDya, LDyb and the optical paths of the combined beams LBya₁₂, LByb₁₂ that return to the Y light receiving systems 74ya, 74yb are folded as appropriate (not shown) such that those optical paths are parallel and spaced apart in the Z axial directions.

FIG. 13A is an oblique view of the tip part of the measuring arm 71A, and FIG. 13B is a plan view, viewed from the +Z direction, of the upper surface of the tip part of the measuring arm 71A. As shown in FIG. 13A and FIG. 13B, the X head 77x radiates the measurement beams LBx₁, LBx₂ (indicated by solid lines in FIG. 13A) from two points (refer to the white circles in FIG. 13B), which are equidistant from a centerline CL of the measuring arm 71A along a straight line LX parallel to the X axis, to the identical irradiation point on the grating RG (refer to FIG. 12A). The irradiation point of the measurement beams LBx₁, LBx₂, namely, the detection point of the X head 77x (refer to symbol DP in FIG. 13B) coincides with the exposure position (refer to FIG. 1), which is the center of the irradiation area IA (i.e., the exposure area) of the illumination light IL radiated to the wafer W. Furthermore, although the measurement beams LBx₁, LBx₂ are in actuality refracted by, for example, the interface surface between the main body part 81 and the air layer, this aspect is shown in a simplified form in FIG. 12A and the like.

As shown in FIG. 12B, the two Y heads 77ya, 77yb are disposed on opposite sides of the centerline CL, one on the +X side and one on the −X side. As shown in FIG. 13A and FIG. 13B, the Y head 77ya radiates measurement beams LBya₁, LBya₂, which are indicated by broken lines in FIG. 13A, from two points (refer to the white circles in FIG. 13B), which are equidistant from the straight line LX along a straight line LYa, to a common irradiation point on the grating RG. The irradiation point of the measurement beams LBya₁, LBya₂, namely, the detection point of the Y head 77ya, is indicated by a symbol DPya in FIG. 13B.

The Y head 77yb radiates measurement beams LByb₁, LByb₂ from two points (refer to the white circles in FIG. 13B), which are symmetric to the emitting points of the measurement beams LBya₁, LBya₂ of the Y head 77ya with respect to the centerline CL, to a common irradiation point DPyb on the grating RG. As shown in FIG. 13B, the detection points DPya, DPyb of the Y heads 77ya, 77yb are disposed along the straight line LX, which is parallel to the X axis.

Here, the main control apparatus 20 determines the position of the fine motion stage WFS1 in the Y axial directions based on the average of the measurement values of the two Y heads 77ya, 77yb. Accordingly, in the present embodiment, the position of the fine motion stage WFS1 in the Y axial directions is measured such that the midpoint DP of the detection points DPya, DPyb serves as the effective measurement point. The midpoint DP coincides with the irradiation point of the measurement beams LBx₁, LBx₂ on the grating RG.

Namely, in the present embodiment, the positional measurements of the fine motion stage WFS1 in the X axial directions and the Y axial directions have a common detection point and this detection point coincides with the exposure position, which is the center of the irradiation area IA (i.e., the exposure area) of the illumination light IL radiated to the wafer W. Accordingly, in the present embodiment, the main control apparatus 20 uses the encoder system 73 to continuously measure—directly below the exposure position (i.e., on the rear surface side of the fine motion stage WFS1)—the position of the fine motion stage WFS1 within the KY plane when the pattern of the reticle R is transferred to a prescribed shot region on the wafer W mounted on the fine motion stage WFS1. In addition, the main control apparatus 20 measures the amount of rotation of the fine motion stage WFS1 in the θz directions based on the difference in the measurement values of the two Y heads 77ya, 77yb.

As shown in FIG. 13A, in the laser interferometer system 75, three length measuring beams LBz₁, LBz₂, LBz₃ emerge from the tip part of the measuring arm 71A and impinge the lower surface of the fine motion stage WFS1. The laser interferometer system 75 comprises three laser interferometers 75a-75c (refer to FIG. 8), each of which radiates one of these three length measurement beams LBz₁, LBz₂, LBz₃.

As shown in FIG. 13A and FIG. 13B, in the laser interferometer system 75, the center of gravity of the three length measurement beams LBz₁, LBz₂, LBz₃ coincides with the exposure position, which is the center of the irradiation area IA (i.e., the exposure area), and the length measurement beams LBz₁, LBz₂, LBz₃ are emitted parallel to the Z axis from three points that correspond to the vertices of an isosceles triangle (or a regular triangle). In this case, the emitting point (i.e., the radiation point) of the length measurement beam LBz₃ is positioned along the centerline CL, and the emitting points (i.e., the radiation points) of the remaining length measurement beams LBz₁, LBz₂ are equidistant from the centerline CL. In the present embodiment, the main control apparatus 20 uses the laser interferometer system 75 to measure the position in the Z axial directions and the amounts of rotation in the θz and θy directions of the fine motion stage WFS1. Furthermore, the laser interferometers 75a-75c are provided to the upper surface of the −Y side end part of the measuring arm 71A (or there above). The length measurement beams LBz₁, LBz₂, LBz₃, which are emitted in the −Z direction from the laser interferometers 75a-75c, transit the reflective surface RP (discussed above), travel along the Y axial directions inside the measuring arm 71A, wherein their optical paths are folded, and emerge from the three points discussed above.

In the present embodiment, a wavelength selecting filter (not shown), which transmits the measurement beams from the encoder system 73 but hinders the transmission of the length measuring beams from the laser interferometer system 75, is provided to the lower surface of the fine motion stage WFS1. In this case, the wavelength selecting filter serves double duty as the reflective surface of the length measurement beams from the laser interferometer system 75.

As can be understood from the explanation above, using the encoder system 73 of the fine motion stage position measuring system 70A and the laser interferometer system 75, the main control apparatus 20 can measure the position of the fine motion stage WFS1 in directions corresponding to six degrees of freedom. In this case, in the encoder system 73, the in-air optical path lengths of the measurement beams are extremely short and substantially equal, and consequently the effects of air turbulence are virtually inconsequential. Accordingly, the encoder system 73 can measure, with high accuracy, the position of the fine motion stage WFS1 within the XY plane (including the θz directions). In addition, because the effective detection point of the encoder system 73 on the grating in the X axial directions and in the Y axial directions and the effective detection point of the laser interferometer system 75 on the lower surface of the fine motion stage WFS1 in the Z axial directions coincide with the center (i.e., the exposure position) of the exposure area IA, so-called Abbé error is suppressed to such a degree that it is substantially inconsequential. Accordingly, using the fine motion stage position measuring system 70A, the main control apparatus 20 can measure, with high accuracy, the position of the fine motion stage WFS1 in the X axial directions, the Y axial directions, and the Z axial directions without Abbé error. In addition, if the coarse motion stages WCS1 are disposed below the projection unit PU and the fine motion stage WFS2 is moveably supported by the coarse motion stages WCS1, then, using the fine motion stage position measuring system 70A, the main control apparatus 20 can measure the position of the fine motion stage WFS2 in the directions corresponding to six degrees of freedom; in particular, the main control apparatus 20 can measure, with high accuracy and without Abbé error, the position of the fine motion stage WFS2 in the X axial directions, the Y axial directions, and the Z axial directions.

In addition, as shown in FIG. 1, the fine motion stage position measuring system 70B, which is provided to the measurement station 300, is substantially bilaterally symmetric with but nevertheless identically configured to the fine motion stage position measuring system 70A. Accordingly, the measuring arm 71B, which is provided to the fine motion stage position measuring system 70B, is oriented such that its longitudinal directions are in the Y axial directions; furthermore, the vicinity of the +Y side end part of the measuring arm 71B is supported such that it is substantially cantilevered from the main frame BD via the support member 72B.

If the coarse motion stages WCS2 are disposed below the alignment apparatus 99 and the fine motion stage WFS2 or WFS1 is moveably supported by the coarse motion stages WCS2, then, using the fine motion stage position measuring system 70B, the main control apparatus 20 can measure the position of the fine motion stage WFS2 or WFS1 in the directions corresponding to six degrees of freedom; in particular, the main control apparatus 20 can measure, with high accuracy and without Abbé error, the position of the fine motion stage WFS2 or WFS1 in the X axial directions, the Y axial directions, and the Z axial directions.

When a device is fabricated using the exposure apparatus 100 of the present embodiment configured as discussed above, the pattern of the reticle R is transferred to each shot region of the plurality of shot regions on the wafer W by performing a step-and-scan type exposure on the wafer W, which is held by one of the fine motion stages (here, the WFS1 as an example) held by the coarse motion stages WCS1 in the exposure station 200. In the step-and-scan type exposure operation, the main control apparatus 20 repetitively performs an inter-shot movement operation, wherein the fine motion stage WFS1 is moved to a scanning start position (i.e., an acceleration start position) in order to expose each of the shot regions on the wafer W, and a scanning exposure operation, wherein the pattern formed on the reticle R is transferred to each of the shot regions by a scanning exposure, based on, for example, the result of the wafer alignment (e.g., the information obtained by converting the array coordinates of each shot region on the wafer W obtained by enhanced global alignment (EGA) to coordinates wherein the second fiducial mark serves as a reference) and the result of the reticle alignment, both alignments being performed in advance. Furthermore, the abovementioned exposure operation is performed in the state wherein the liquid Lq is held between the tip lens 191 and the wafer W, namely, the abovementioned exposure operation is performed by an immersion exposure. In addition, the operation is performed in order starting with the shot regions positioned on the +Y side and proceeding toward the shot regions positioned on the −Y side. Furthermore, EGA is disclosed in detail in, for example, U.S. Pat. No. 4,780,617.

In the exposure apparatus 100 of the present embodiment, during the sequence of exposure operations discussed above, the main control apparatus 20 uses the fine motion stage position measuring system 70A to measure the position of the fine motion stage WFS1 (i.e., the wafer W) and, based on this measurement result, controls the position of the wafer W.

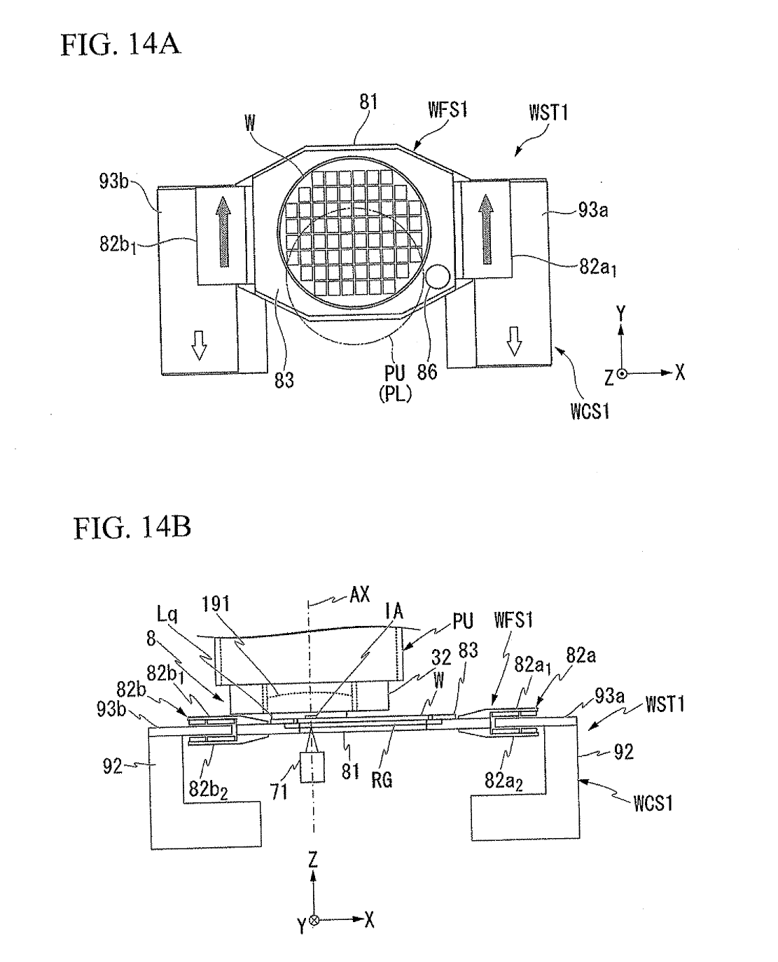

Furthermore, during the scanning exposure operation discussed above, the wafer W must be driven in the Y axial directions at a high acceleration; however, in the exposure apparatus 100 of the present embodiment, as shown in FIG. 14A, the main control apparatus 20 scans the wafer W in the Y axial directions by driving only the fine motion stage WFS1 in the Y axial directions (refer to the solid arrows in FIG. 14A; and, as needed, in the directions corresponding to the other five degrees of freedom) without, as a rule, driving the coarse motion stages WCS1. This is because to drive the wafer W at a high acceleration, it is advantageous to drive the wafer W using only the fine motion stage WFS1, which is lighter than the coarse motion stages WCS1. In addition, as discussed above, the position measurement accuracy of the fine motion stage position measuring system 70A is higher than that of the wafer stage position measuring system 16A, and therefore it is advantageous to drive the fine motion stage WFS1 during the scanning exposure. Furthermore, during the scanning exposure, the action of the reaction force (refer to the outlined arrows in FIG. 14A) generated by the drive of the fine motion stage WFS1 drives the coarse motion stages WCS1 in a direction opposite that of the fine motion stage WFS1. Namely, the coarse motion stages WCS1 function as countermasses and conserve the momentum of the system that constitutes the entire wafer stage WST1, and thereby the center of gravity does not move; therefore, the problem wherein, for example, a bias load acts on the base plate 12 owing to the drive of the fine motion stage WFS1 during a scan does not arise.

Moreover, when the inter-shot movement operation (i.e., stepping) is performed in the X axial directions, the fine motion stage WFS1 can move in the X axial directions by only a small amount; therefore, as shown in FIG. 14B, the main control apparatus 20 moves the wafer W in the X axial directions by driving the coarse motion stages WCS1 in the X axial directions.

In parallel with the exposure of the wafer W on one of the fine motion stages, for example, the fine motion stage WFS1, as discussed above, wafer exchange, wafer alignment, and the like are performed on the other fine motion stage, in this case, the fine motion stage WFS2. Wafer exchange is performed when the coarse motion stages WCS2 that support the fine motion stage WFS2 are at a prescribed wafer exchange position in the vicinity of the measurement station 300 (i.e., at a position below the chuck unit 102 discussed above); in detail, the chuck unit 102 and the wafer transport arm 118 both unload an exposed wafer W from the fine motion stage WFS2 and load a new wafer W onto the fine motion stage WFS2.

Wafer exchange will now be discussed in detail. Furthermore, the chucking and unchucking of the wafer by the wafer holder will be explained in detail later; here, it is principally the operation of the chuck unit 102 during the wafer exchange that will be explained.

Assuming that wafer exchange has begun, the fine motion stage WFS2 that holds the exposed wafer W is at the wafer exchange position below the chuck unit 102 and is supported by the coarse motion stages WCS2 (refer to FIG. 5).

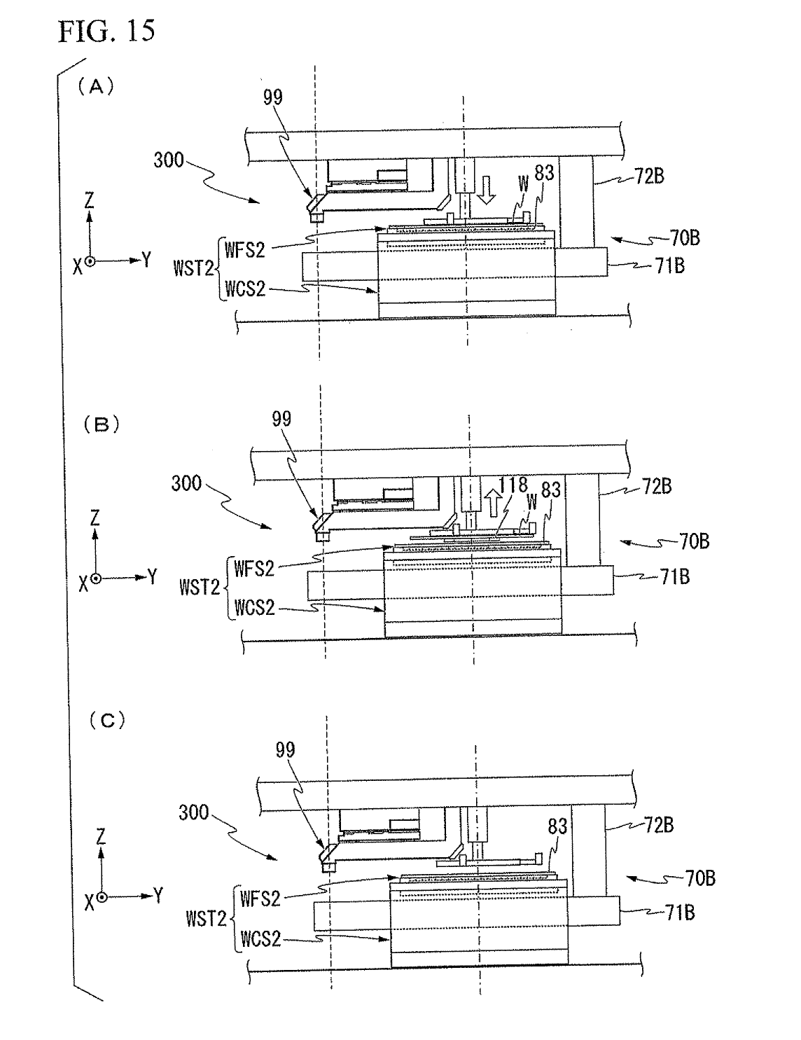

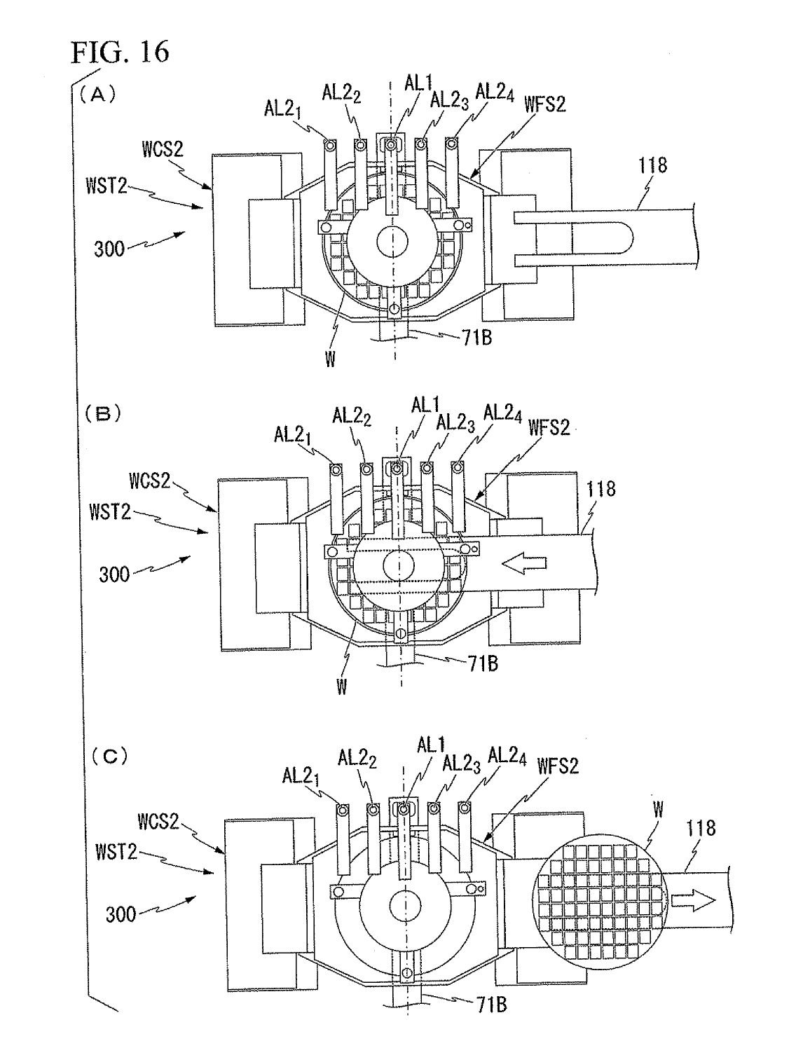

First, the main control apparatus 20 controls the drive part 104 of the chuck unit 102 so as to drive the Bernoulli chuck 108 downward (refer to FIG. 15(A)). During this driving process, the main control apparatus 20 monitors the measurement value of the gap sensor 112. Furthermore, when the measurement value of the gap sensor 112 reaches a prescribed value, for example, approximately several microns, the main control apparatus 20 both stops the downward drive of the Bernoulli chuck 108 and adjusts the flow velocity of the air blown out from the Bernoulli chuck 108 such that the gap of several microns is maintained. Thereby, the Bernoulli chuck 108 noncontactually chucks the wafer W from above (refer to FIG. 16(A)) with a clearance of approximately several microns.

Next, the main control apparatus 20 controls the drive part 104 so as to drive the Bernoulli chuck 108, which noncontactually chucks the wafer W, upward (refer to FIG. 15(B)). Furthermore, the main control apparatus 20 inserts the wafer transport arm 118, which was standing by at the standby position in the vicinity of the wafer exchange position, into the space below the wafer W held by the Bernoulli chuck 108 (refer to FIG. 15(B) and FIG. 16(B)), releases the chucking action of the Bernoulli chuck 108, and then drives the Bernoulli chuck 108 slightly upward. Thereby, the wafer W is held from below by the wafer transport arm 118.

Furthermore, the main control apparatus 20 transports the wafer W via the wafer transport arm 118 to a wafer unloading position (e.g., the position at which the wafer is transferred to and from the coater-developer (on the unloading side)), which is below the chuck unit 102 and spaced apart from the wafer exchange position in the +X direction, and mounts the wafer W at that wafer unloading position. FIG. 16(C) shows an aspect wherein the wafer transport arm 118 is moving away from the wafer exchange position, and FIG. 15(C) shows the state wherein the wafer transport arm 118 is spaced apart from the wafer exchange position.

Next, the main control apparatus 20 loads a new (i.e., an unexposed) wafer W on the fine motion stage WFS2 using a procedure that is roughly the reverse of the unloading procedure described above.

Namely, the main control apparatus 20 controls the wafer transport arm 118 so as to transport the wafer W, which is at the wafer loading position (e.g., at the position at which the wafer is transferred to and from the coater-developer (on the loading side)), via the wafer transport arm 118 to the wafer exchange position below the chuck unit 102.

Next, the main control apparatus 20 drives the Bernoulli chuck 108 slightly downward and begins the chucking of the wafer W by the Bernoulli chuck 108. Furthermore, the main control apparatus 20 drives the Bernoulli chuck 108, which has chucked the wafer W, slightly upward and retracts the wafer transport arm 118 to the standby position discussed above.

Next, based on the rotational error and the positional deviation in the X axial directions and the Y axial directions of the wafer W supplied from the signal processing system 116 discussed above, the main control apparatus 20 uses the fine motion stage drive system 52B (and a coarse motion stage drive system 51B) to adjust, while monitoring the measurement values of the relative position measuring instrument 22B and the wafer stage position measuring system 16B, the position within the XY plane (including θz rotation) of the fine motion stage WFS2 such that the rotational error and positional deviation of the wafer W are corrected.

Next, the main control apparatus 20 drives the Bernoulli chuck 108 downward as far as the position at which the rear surface of the wafer W contacts the wafer holder of the fine motion stage WFS2, unchucks the wafer W from the Bernoulli chuck 108, and then drives the Bernoulli chuck 108 upward by a prescribed amount. Thereby, the new wafer W is loaded on the fine motion stage WFS2. The new wafer W then undergoes alignment.

When a wafer alignment is performed, the main control apparatus 20 first drives the fine motion stage WFS2 to position the measuring plate 86 mounted on the fine motion stage WFS2 directly below the primary alignment system AL1, which the main control apparatus 20 uses to detect the second fiducial mark. Furthermore, as disclosed in, for example, U.S. Patent Application Publication No. 2008/0088843, the main control apparatus 20 moves the wafer stage WST2 in, for example, the direction and positions the wafer stage WST2 at a plurality of locations along the travel path; furthermore, with each positioning, the main control apparatus 20 uses at least one of the alignment systems AL1, AL2₁-AL2₄ to detect the position of an alignment mark in the alignment shot region (i.e., the sample shot region). Let us consider a case involving, for example, four positionings: during the first positioning, for example, the main control apparatus 20 uses the primary alignment system AL1 and the secondary alignment systems AL2₂, AL2₃ to detect the alignment marks (hereinbelow, also called sample marks) in three sample shot regions; during the second positioning, the main control apparatus 20 uses the alignment systems AL1, AL2₁-AL2₄ to detect five sample marks on the wafer W; during the third positioning, the main control apparatus 20 uses the alignment systems AL1, AL2₁-AL2₄ to detect five sample marks; and during the fourth positioning, the main control apparatus 20 uses the primary alignment system AL1 and the secondary alignment systems AL2₂, AL2₃ to detect three sample marks. Thereby, the positions of the alignment marks in a total of 16 alignment shot regions can be obtained in a markedly shorter time than in the case wherein a single alignment system sequentially detects the 16 alignment marks. In this case, the alignment systems AL1, AL2₂, AL2₃ detect—in conjunction with the abovementioned operation of moving the wafer stage WST2—the plurality of alignment marks (i.e., sample marks) arrayed along the Y axial directions and sequentially disposed within the detection areas (e.g., corresponding to the areas irradiated by the detection beams). Consequently, when the abovementioned alignment marks are measured, it is not necessary to move the wafer stage WST2 in the X axial directions.

In the present embodiment, when performing the wafer alignment, including the detection of the second fiducial mark, the main control apparatus 20 uses the fine motion stage position measuring system 70B, including the measuring arm 71B, to measure the position within the XY plane of the fine motion stage WFS2 supported by the coarse motion stages WCS2 during the wafer alignment. However, the present invention is not limited thereto; for example, if the fine motion stage WFS2 is moved integrally with the coarse motion stages WCS2 during the wafer alignment, then the wafer alignment may be performed while measuring the position of the wafer W via the wafer stage position measuring system 16B as discussed above. In addition, because the measurement station 300 and the exposure station 200 are spaced apart, the position of the fine motion stage WFS2 during the wafer alignment and during the exposure is controlled using different coordinate systems. Accordingly, the main control apparatus 20 converts the array coordinates of each of the shot regions on the wafer W, which were obtained as a result of the wafer alignment, to array coordinates wherein the second fiducial mark serves as a reference.

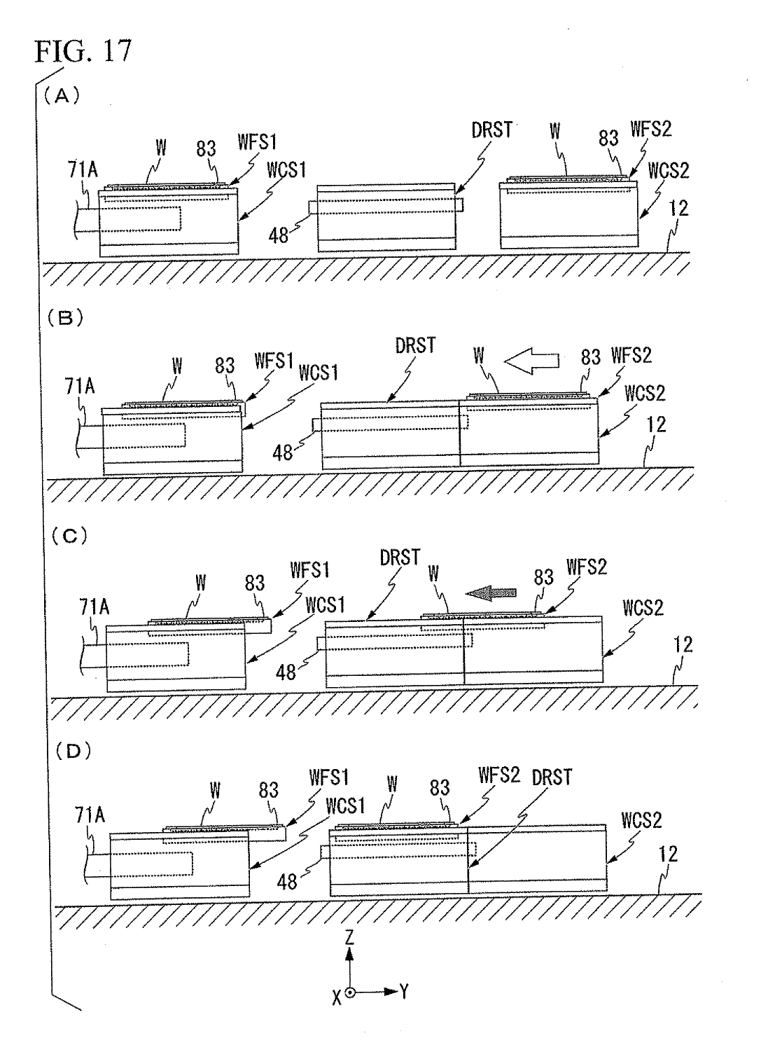

Thus, although the wafer alignment of the wafer W held by the fine motion stage WFS2 ends, the exposure of the wafer W held by the fine motion stage WFS1 at the exposure station 200 continues. FIG. 17(A) shows the positional relationships between the coarse motion stages WCS1, the coarse motion stages WCS2, and the relay stage DRST at the point at which the alignment of the wafer W has ended.

The main control apparatus 20 drives the wafer stage WST2 via the coarse motion stage drive system 51B by a prescribed distance in the direction, as shown by the outlined arrow in FIG. 17(B), so as to bring the wafer stage WST2 into contact or close proximity, namely, spaced apart by approximately 500 μm, with the relay stage DRST, which is stationary at the prescribed standby position (i.e., a position that substantially coincides with the center position between the optical axis AX of the projection optical system PL and the center of detection of the primary alignment system AL1).

Next, the main control apparatus 20 controls the electric currents flowing to the YZ coils of the fine motion stage drive systems 52B, 52C so as to drive the fine motion stage WFS2 in the −Y direction by Lorentz's forces, as shown by the solid arrow in FIG. 17(C), and transfers the fine motion stage WFS2 from the coarse motion stages WCS2 to the relay stage DRST. FIG. 17(D) shows the state wherein the transfer of the fine motion stage WFS2 to the relay stage DRST has ended.

In the state wherein the relay stage DRST and the coarse motion stages WCS2 are placed on standby at the position shown in FIG. 17(D), the main control apparatus 20 waits for the exposure of the wafer W on the fine motion stage WFS1 to end.

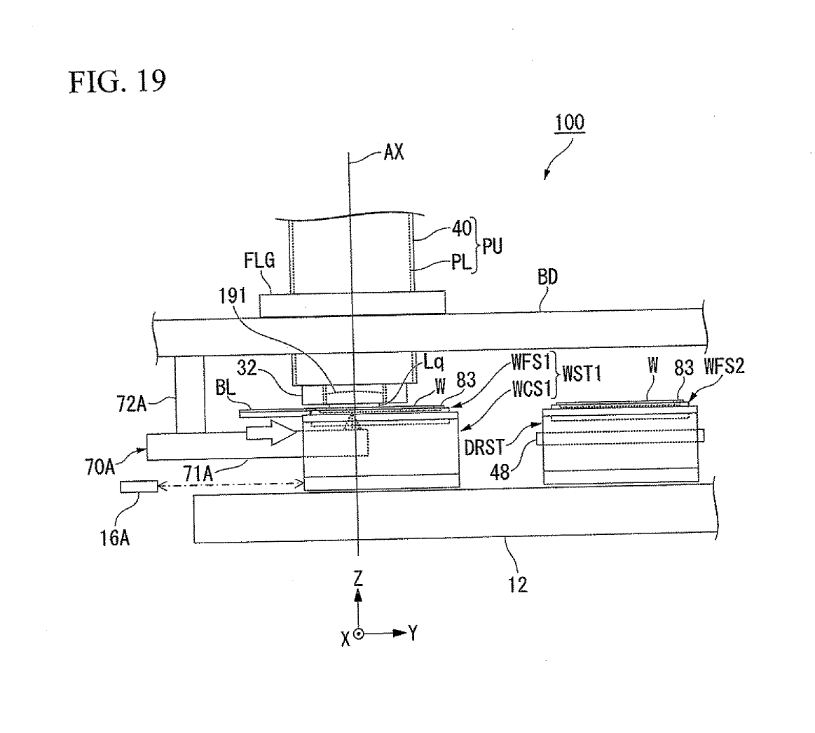

FIG. 19 shows the state of the wafer stage WST1 immediately after the exposure has ended.

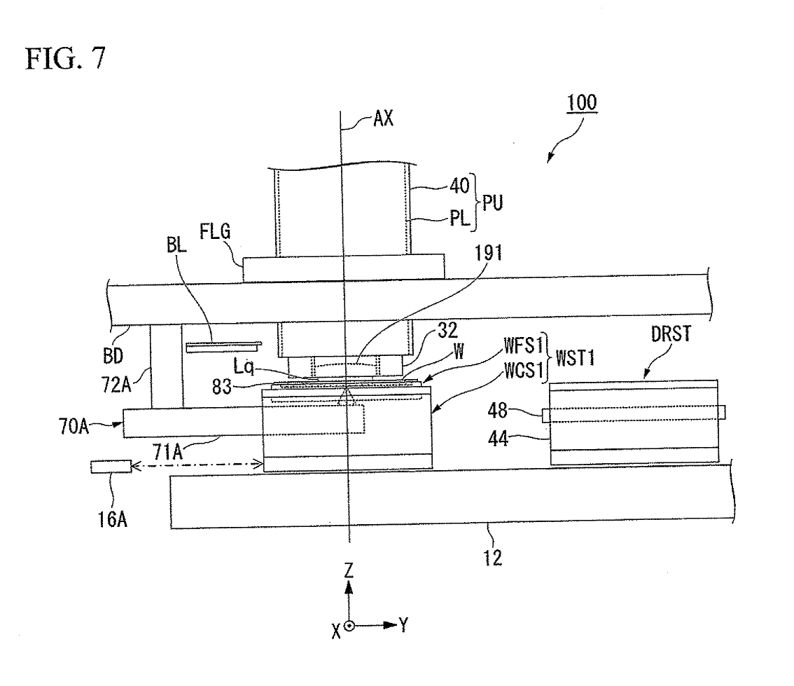

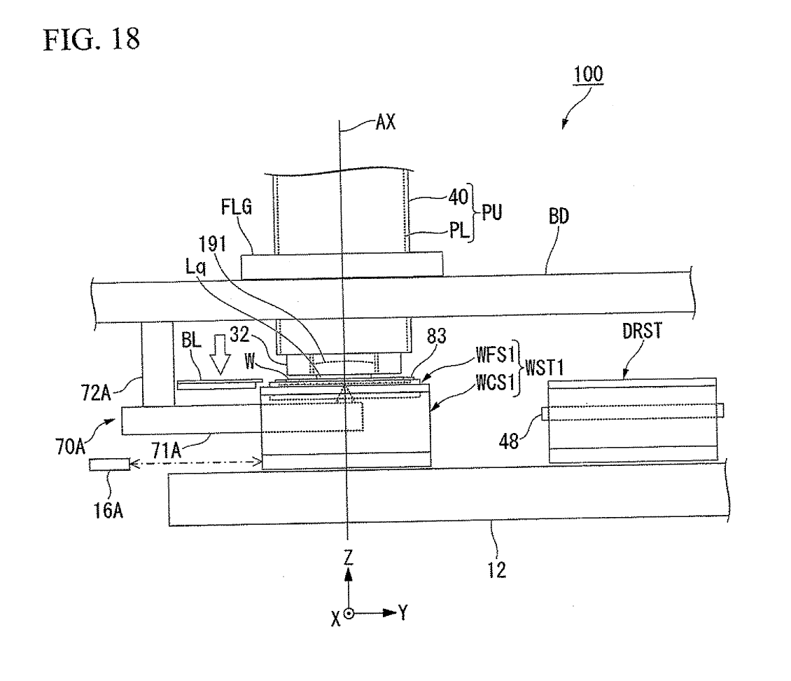

Prior to the end of the exposure, as shown by the outlined arrow in FIG. 18, the main control apparatus 20 uses a blade drive system 58 to drive a movable blade BL downward by a prescribed amount from the state shown in FIG. 7. Thereby, as shown in FIG. 18, the upper surface of the movable blade BL and the upper surface of the fine motion stage WFS1 (and the wafer W), which is positioned below the projection optical system PL, are positioned coplanarly. Furthermore, the main control apparatus 20 waits in this state for the exposure to end.

Furthermore, when the exposure has ended, the main control apparatus 20 uses the blade drive system 58 to drive the movable blade BL by a prescribed amount in the +Y direction (refer to the outlined arrow in FIG. 19), and the movable blade BL is either brought into contact with the fine motion stage WFS1 or made proximate therewith a clearance of approximately 300 μm. Namely, the main control apparatus 20 sets the movable blade BL and the fine motion stage WFS1 to a “scrum” state.

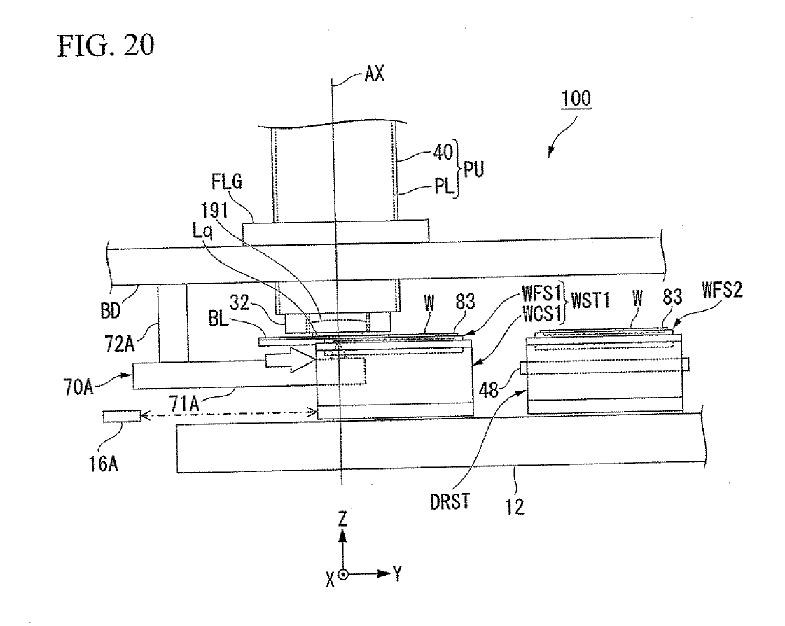

Next, as shown in FIG. 20, the main control apparatus 20 drives the movable blade BL integrally with the wafer stage WST1 in the +Y direction (refer to the outlined arrow in FIG. 20) while maintaining the “scrum” state between the movable blade BL and the fine motion stage WFS1. Thereby, an immersion space, which is formed by the liquid Lq held between the fine motion stage WFS1 and the tip lens 191, is transferred from the fine motion stage WFS1 to the movable blade BL. FIG. 20 shows the state immediately before the immersion space, which is formed from the liquid Lq, is transferred from the fine motion stage WFS1 to the movable blade BL. In the state shown in FIG. 20, the liquid Lq is held between the tip lens 191 on one side and the fine motion stage WFS1 and the movable blade BL on the other side.

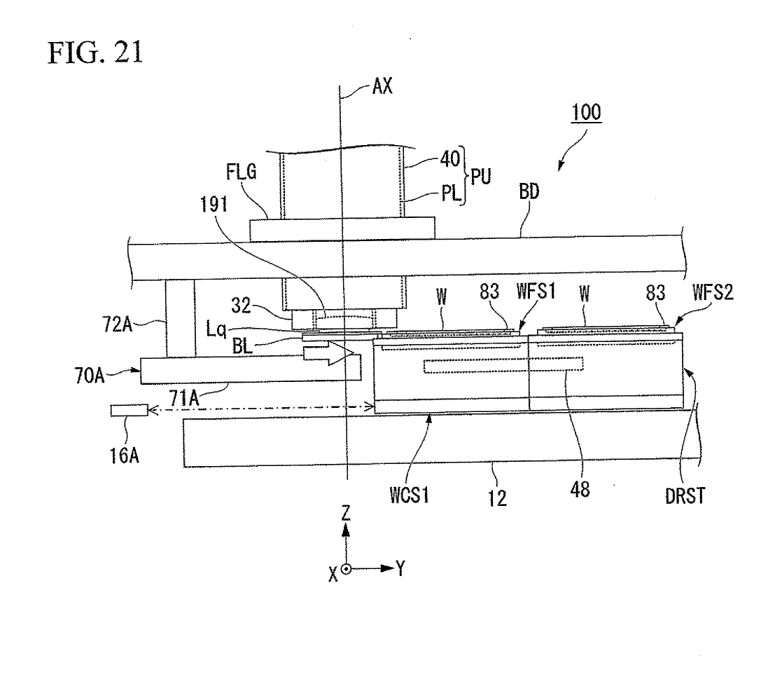

Furthermore, when the transfer of the immersion space from the fine motion stage WFS1 to the movable blade BL has ended, as shown in FIG. 21, the coarse motion stages WCS1, which hold the fine motion stage WFS1, come into contact or close proximity, with a clearance of approximately 300 μm, with the relay stage DRST, which is holding the fine motion stage WFS2 at the standby position discussed above and standing by such that it is proximate to the coarse motion stages WCS2. In the state wherein the coarse motion stages WCS1 that hold the fine motion stage WFS1 are moving in the +Y direction, the main control apparatus 20 uses the transport member drive system 54 to insert the transport member 48 of the transport apparatus 46 into the space of the coarse motion stages WCS1.

Furthermore, when the coarse motion stages WCS1 that hold the fine motion stage WFS1 come into contact or close proximity with the relay stage DRST, the main control apparatus 20 drives the transport member 48 upward and supports the fine motion stage WFS1 from below.

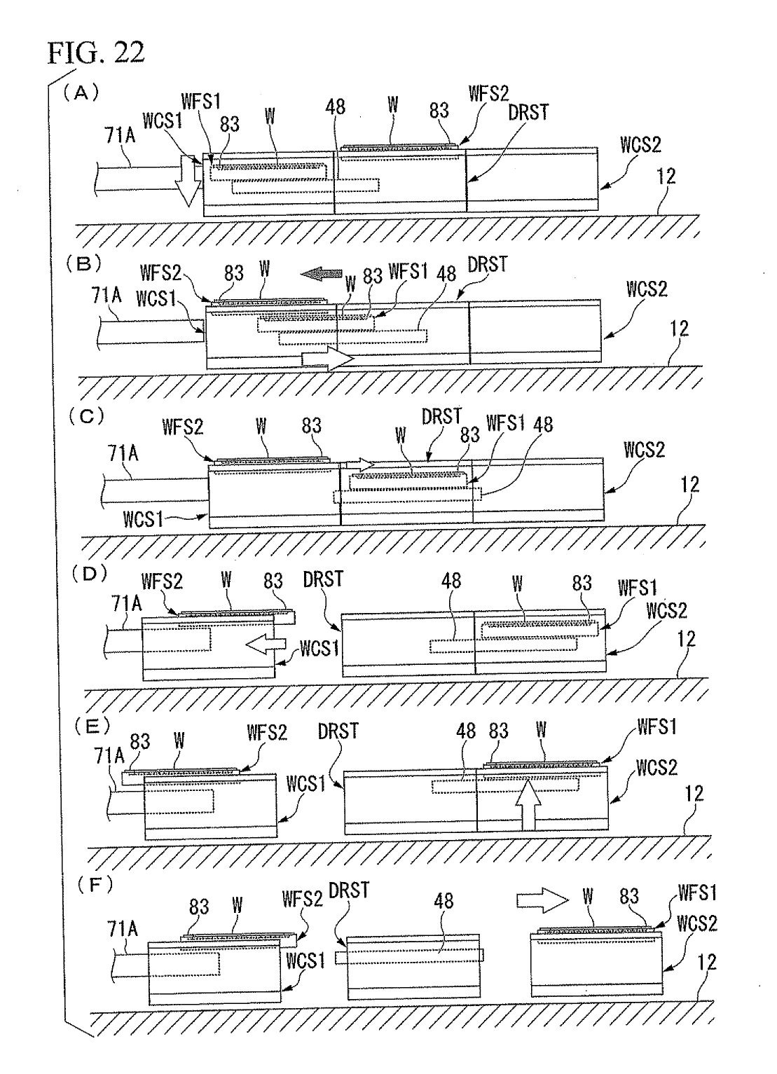

Furthermore, in this state, the main control apparatus 20 moves the two coarse motion stages WCS1 in directions away from each other. Thereby, the fine motion stage WFS1 can be separated from the coarse motion stages WCS1. Accordingly, the main control apparatus 20 drives the transport member 48, which supports the fine motion stage WFS1, downward, as shown by the outlined arrow in FIG. 22(A).

Furthermore, the main control apparatus 20 moves the pair of coarse motion stages WCS1 to near the position at which the pair holds the fine motion stage.

Next, the main control apparatus 20 moves the transport member 48, which supports the fine motion stage WFS1 from below, to the interior of the stage main body 44 of the relay stage DRST. FIG. 22(B) shows the state wherein the transport member 48 is being moved. In addition, in parallel with the movement of the transport member 48, the main control apparatus 20 controls the electric currents that flow to Y drive coils of the fine motion stage drive systems 52C, 52A so as to drive the fine motion stage WFS2 in the −Y direction by Lorentz's forces, as shown by the solid arrow in FIG. 22(B), and then transfers (i.e., slides) the fine motion stage WFS2 from the relay stage DRST to the coarse motion stages WCS1.

In addition, the main control apparatus 20 houses the transport member main body of the transport member 48 in the space of the relay stage DRST such that the fine motion stage WFS1 is completely housed in the space of the relay stage DRST, and then moves the movable member, which holds the fine motion stage WFS1, in the +Y direction on the transport member main body (refer to the outlined arrow in FIG. 22(C)).

Next, the main control apparatus 20 moves the coarse motion stages WCS1, which held the fine motion stage WFS2, in the −Y direction and transfers the immersion space, which is held between the movable blade BL and the tip lens 191, from the movable blade BL to the fine motion stage WFS2. The procedure of transferring the immersion space (i.e., the liquid Lq) is performed in the reverse order of the procedure of transferring the immersion area from the fine motion stage WFS1 to the movable blade BL discussed above.

Furthermore, prior to the start of an exposure, the main control apparatus 20 uses the pair of reticle alignment systems RA₁, RA₂, the pair of first fiducial marks on the measuring plate 86 of the fine motion stage WFS2, and the like, all of which were discussed above, to perform a reticle alignment using a procedure identical to that of a regular scanning stepper (e.g., the procedure disclosed in U.S. Pat. No. 5,646,413). FIG. 22(D) shows the fine motion stage WFS2, which is undergoing a reticle alignment, and the coarse motion stages WCS1, which hold the fine motion stage WFS2. Furthermore, based on the results of the reticle alignment and of the wafer alignment (i.e., the array coordinates of each shot region on the wafer W wherein the second fiducial mark serves as a reference), the main control apparatus 20 performs step-and-scan type exposure operations to transfer the pattern of the reticle R to the plurality of shot regions on the wafer W. As can be seen clearly also from FIG. 22(E) and FIG. 22(F), these exposures are performed after the reticle alignment; first, the fine motion stage WFS2 is returned to the −Y side and the shot regions on the wafer W are exposed in sequence starting with the +Y side shot region and ending with the −Y side shot region.

The following types of operations are performed in parallel with the abovementioned transfer of the immersion space, the reticle alignment, and the exposures.

Namely, as shown in FIG. 22(D), the main control apparatus 20 moves the transport member 48, which holds the fine motion stage WFS1, into the space of the coarse motion stages WCS2. At this time, the main control apparatus 20 both moves the transport member 48 and moves the movable member that holds the fine motion stage WFS1 in the +Y direction on the transport member main body.

Next, the main control apparatus 20 both moves the two coarse motion stages WCS2 away from one another and drives the transport member 48, which holds the fine motion stage WFS1, upward as shown by the outlined arrow in FIG. 22(E) so as to position the fine motion stage WFS1 at a height at which each pair of the slider parts provided by the fine motion stage WFS1 can engage with a corresponding pair of the stator parts of the coarse motion stages WCS2.

Furthermore, the main control apparatus 20 brings the two coarse motion stages WCS2 into close proximity with one another. Thereby, the pair of coarse motion stages WCS2 supports the fine motion stage WFS1, which holds the exposed wafer W.

Next, the main control apparatus 20 drives the coarse motion stages WCS2, which support the fine motion stage WFS1, in the +Y direction as shown by the outlined arrow in FIG. 22(F) so as to move the coarse motion stages WCS2 to the measurement station 300.

Subsequently, the main control apparatus 20 performs procedures on the fine motion stage WFS1 identical to those discussed above, such as exchanging the wafer, detecting the second fiducial mark, and aligning the wafer.

Furthermore, the main control apparatus 20 converts the array coordinates of each of the shot regions on the wafer W, which were obtained as a result of the wafer alignment, to array coordinates wherein the second fiducial mark serves as a reference. In this case, too, when the alignment is performed, the fine motion stage position measuring system 70B is used to measure the position of the fine motion stage WFS1.

Thus, although the wafer alignment of the wafer W held by the fine motion stage WFS1 ends, the exposure of the wafer W held by the fine motion stage WFS2 at the exposure station 200 continues.

Furthermore, as discussed above, the main control apparatus 20 mounts the fine motion stage WFS1 on the relay stage DRST. In the state wherein the relay stage DRST and the coarse motion stages WCS2 are placed on standby at the standby position discussed above, the main control apparatus 20 waits for the exposure of the wafer W on the fine motion stage WFS2 to end.

Subsequently, the same process is repetitively performed alternately using the fine motion stage WFS1 and the fine motion stage WFS2, and thereby the exposing process is performed continuously on a plurality of the wafers W.

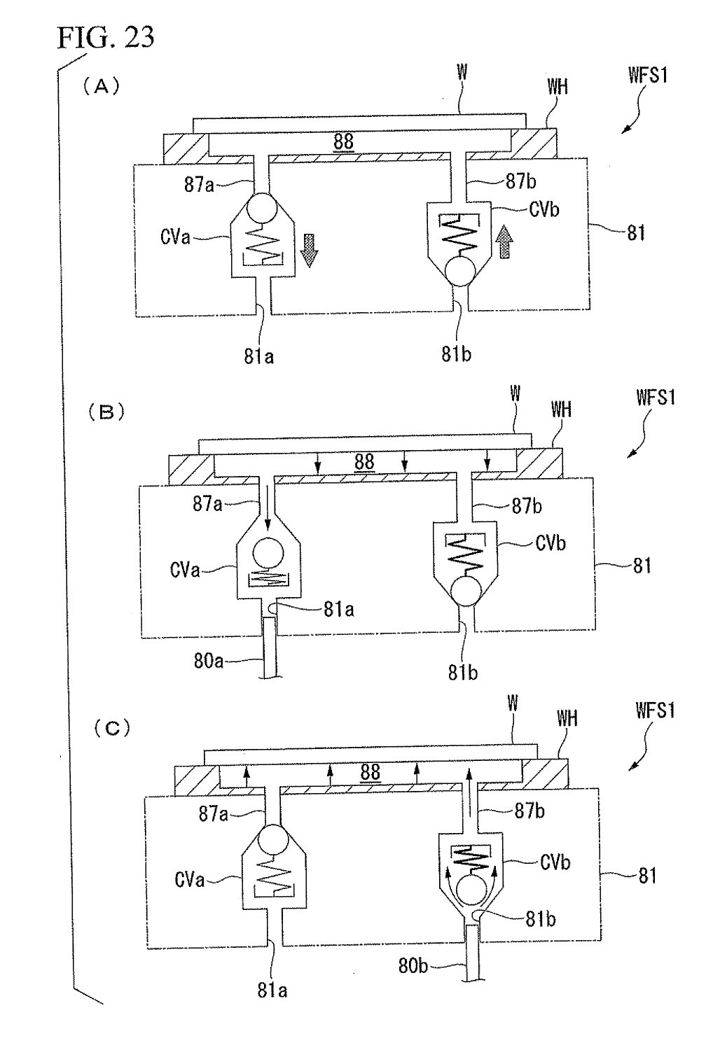

Next, the chucking and unchucking of the wafer W by the wafer holder will be explained. FIG. 23(A) schematically shows the configuration of the fine motion stage WFS1. Furthermore, while parts (A)-(C) of FIG. 23 show the fine motion stage WFS1, the fine motion stage WFS2 is identically configured.

As shown in FIG. 23(A), a suction opening 81a is formed in the main body part 81 of the fine motion stage WFS1. The position of the suction opening 81a is not particularly limited, and the suction opening 81a can be formed in, for example, the side surface or the lower surface of the main body part 81. In addition, inside the main body part 81, a piping member 87a is provided that brings an opening formed in a bottom part of a wafer holder WET, an external space that passes through the suction opening 81a, and a pressure reducing chamber 88 formed between the wafer holder WH and the rear surface of the wafer W into communication. A check valve CVa is disposed along the conduit of the piping member 87a. The check valve CVa limits the direction in which a gas flows inside the piping member 87a to a single direction (refer to the solid arrow in FIG. 23(A)) that proceeds from the pressure reducing chamber 88 to the external space, namely, the reduced pressure state of the pressure reducing chamber 88 is maintained by ensuring that gas at a pressure higher than that of the gas inside the pressure reducing chamber 88 does not flow from the external space into the pressure reducing chamber 88.

In addition, the exposure apparatus 100 comprises a suction piping 80a that, when the wafer stage WST1 (or WST2) is positioned at the wafer exchange position shown in FIG. 5 for the purpose of exchanging the wafer W using the chuck unit 102, is positioned such that one end of the suction piping 80a is inserted inside the piping member 87a via the suction opening 81a, as shown in parts (B) and (C) of FIG. 23. The other end of the suction piping 80a is connected to a vacuum pump (not shown). When the wafer W is mounted on the wafer holder WH, the main control apparatus 20 (refer to FIG. 8) controls the vacuum pump so as to suction the gas from the pressure reducing chamber 88. The suction piping 80a and the piping member 87a are tightly sealed to one another by, for example, an O-ring (not shown). Thereby, the pressure inside the pressure reducing chamber 88 falls below the pressure of the external space, which chucks the wafer W to the wafer holder WH. In addition, when the pressure inside the pressure reducing chamber 88 reaches a prescribed pressure, the main control apparatus 20 stops the suctioning of the gas from the pressure reducing chamber 88 by the vacuum pump. Subsequently, even if the wafer stage WST1 (or WST2) moves from the wafer exchange position and the suction piping 80a is pulled out of the piping member 87a, the check valve CVa tightly closes the conduit of the piping member 87a, and therefore the state wherein the pressure of the pressure reducing chamber 88 is reduced and the state wherein the wafer W is chucked to the wafer holder WH are maintained.

In addition, because the check valve CVa maintains the reduced pressure state of the pressure reducing chamber 88, there is no need to connect a piping member (e.g., a tube) to the fine motion stages WFS1, WFS2 for the purpose of, for example, suctioning the gas from the pressure reducing chamber 88. Accordingly, the fine motion stages WFS1, WFS2 are able to be detached from the coarse motion stages WCS1, WCS2 and it is possible to, for example, transfer the fine motion stage WFS1 (or WFS2) between the two coarse motion stages WCS1, WCS2 and the relay stage DRST without hindrance.

In addition, if the pressure reducing chamber 88 is continuously maintained in the reduced pressure state, then it is difficult to hold the wafer W using the Bernoulli chuck 108 (refer to FIG. 5) when unloading the wafer W; consequently, the main body part 81 is provided with a piping member 87b for the purpose of releasing the reduced pressure state of the pressure reducing chamber 88, as shown in FIG. 23(A). As in the piping member 87a, the piping member 87b brings the pressure reducing chamber 88 and the external space into communication via an opening, which is formed in the bottom part of the wafer holder WH, and a release opening 81b, which is formed in the main body part 81. The position of the release opening 81b is not particularly limited, and the release opening 81b can be formed in, for example, the side surface or the lower surface of the main body part 81. A check valve CVb is disposed along the conduit of the piping member 87b. The check valve CVb limits the direction in which the gas inside the piping member 87b flows to a single direction (refer to the solid arrow in FIG. 23(A)) that proceeds from the external space to the pressure reducing chamber 88. Furthermore, the spring constant of a spring, which urges a valve member (e.g., a ball in parts (A)-(C) of FIG. 23) of the check valve CVb toward a closed position, is set such that the valve member does not move toward the open position in the state (shown in FIG. 23(A)) wherein the pressure reducing chamber 88 has become a reduced pressure space (i.e., such that the check valve does not open in the state shown in FIG. 23(B)).

In addition, the exposure apparatus 100 comprises a gas supply piping 80b, which is positioned such that, when the wafer stage WST1 (or WST2) is positioned at the wafer exchange position shown in FIG. 5, one end of the gas supply piping 80b is inserted from the release opening 81b into the piping member 87b, as shown in parts (B) and (C) of FIG. 23. The other end of the gas supply piping 80b is connected to a gas supply apparatus (not shown). When the wafer W is to be unloaded, the main control apparatus 20 controls the gas supply apparatus so as to blow out the high pressure gas inside the piping member 87b. Thereby, the check valve CVb transitions to an open state and high pressure gas is introduced into the pressure reducing chamber 88, which releases the chucking of the wafer W by the wafer holder WH. In addition, the blowing out of the gas, which was introduced from the gas supply apparatus to the pressure reducing chamber 88, from below and toward the rear surface of the wafer W cancels the self weight of the wafer W. Namely, the gas supply apparatus assists the operation wherein the Bernoulli chuck 108 holds (i.e., lifts up) the wafer W. Accordingly, the force with which the Bernoulli chuck 108 chucks the wafer may be small, which makes it possible to reduce the size of the chuck unit 102. Furthermore, if a wafer holder of the type that holds the wafer by electrostatic chucking is used as the wafer holder WH, then a battery that can charge the fine motion stage may be installed and that battery may be charged while the wafer is being exchanged at the wafer exchange position shown in FIG. 5. In this case, a power receiving terminal may be provided to the fine motion stage and a power supply terminal may be disposed in the vicinity of the wafer exchange position and positioned such that it is electrically connected to the abovementioned power receiving terminal when the wafer stage is positioned at the wafer exchange position.

According to the exposure apparatus 100 of the present embodiment as explained in detail above, when the fine motion stage WFS2 (or WFS1) that holds the wafer W is positioned at the wafer exchange position below the chuck unit 102, the Bernoulli chuck 108 of the chuck unit 102 can hold the wafer W noncontactually from above and unload the wafer W from the fine motion stage WFS2 (or WFS1). Consequently, to unload the wafer W from the fine motion stage WFS2 (or WFS1), there is no need to form a notch, which is for housing an arm and the like used for that unloading, in the wafer holder WH on the fine motion stage WFS2 (or WFS1). In addition, by noncontactually holding the wafer W from above with the Bernoulli chuck 108, the wafer W can be loaded onto the fine motion stage WFS2 (or WFS1). Consequently, to load the wafer W onto the fine motion stage WFS2 (or WFS1), there is no need to form the notch, which is for housing an area and the like used in that loading, in the wafer holder WH on the fine motion stage WFS2 (or WFS1). In addition, according to the exposure apparatus 100 of the present embodiment, there is no need to provide to the fine motion stage WFS2 (or WFS1) a vertically moving member (also called a centering member or a center table) for transferring the wafer. Accordingly, the wafer holder WH on the fine motion stage WFS1 (or WFS2) can evenly chuck the wafer W over its entire surface, including the surrounding shot regions, and thereby can satisfactorily maintain the planarity of the wafer W over its entire surface.

In addition, according to the exposure apparatus 100 of the present embodiment, a measurement surface, wherein the grating RG is formed, is provided to one surface of each of the fine motion stages WFS1 and WFS2 such that this measurement surface is substantially parallel to the XY plane. The fine motion stage WFS1 (or WFS2) is held by the coarse motion stages WCS1 (or WCS2) such that it is capable of relative motion with respect to the coarse motion stages WCS1 (or WCS2) along the XY plane. Furthermore, the fine motion stage position measuring system 70A (or 70B) comprises the X head 77x and the Y heads 77ya, 77yb, which are disposed such that they oppose the measurement surface wherein the grating RG is formed inside the space of the coarse motion stages WCS1, radiates the pairs of measurement beams LBx₁, LBx₂, LBya₁, LBya₂, LByb₁, LByb₂ to the measurement surface, and receives the lights of the measurement beams (e.g., the combined beams LBx₁₂, LBya₁₂, LByb₁₂ of the first order diffraction beams, which are produced by the grating RG, of the measurement beams) from the measurement surface. Furthermore, the fine motion stage position measuring system 70A (or 70B) measures, based on the outputs of the X head 77x and the Y heads 77ya, 77yb, the position at least within the XY plane (including the rotation in the θz directions) of the fine motion stage WFS1 (or WFS2). Consequently, the X head 77x and the Y heads 77ya, 77yb radiate the pairs of measurement beams LBx₁, LBx₂, LBya₁, LBya₂, LByb₁, LByb₂ to the measurement surface wherein the grating RG of the fine motion stage WFS1 (or WFS2) is formed, which makes it possible to accurately measure the position of the fine motion stage WFS1 (or WFS2) within the XY plane via the so-called rear surface measurement method. Furthermore, the main control apparatus 20 drives the fine motion stage WFS1 (or WFS2) independently or integrally with the coarse motion stages WCS1 (or WCS2) based on the position measured by the fine motion stage position measuring system 70A (or 70B) via either the fine motion stage drive system 52A or the fine motion stage drive system 52A and the coarse motion stage drive system 51A (or via either the fine motion stage drive system 52B or the fine motion stage drive system 52B and the coarse motion stage drive system 51B). In addition, as discussed above, there is no need to provide a vertically moving member on the fine motion stage, and therefore even adopting the abovementioned rear surface measurement technique poses no particular obstacles.

In addition, in the exposure station 200 according to the exposure apparatus 100 of the present embodiment, the wafer W mounted on the fine motion stage WFS1 (or WFS2), which is held such that it is capable of moving relative to the coarse motion stages WCS1, is exposed with the exposure light IL through the reticle R and the projection optical system PL. At this time, the main control apparatus 20 uses the encoder system 73 of the fine motion stage position measuring system 70A, which comprises the measuring arm 71A that opposes the grating RG disposed on the fine motion stage WFS1 (or WFS2), to measure the position of the fine motion stage WFS1 (or WFS2), which is moveably held by the coarse motion stages WCS1, within the XY plane. In this case, a space is formed inside the coarse motion stages WCS1 and each of the heads of the fine motion stage position measuring system 70A are disposed in that space; therefore, space exists only between the fine motion stage WFS1 (or WFS2) and the heads of the fine motion stage position measuring system 70A. Accordingly, each of the heads can be disposed in close proximity to the fine motion stage WFS1 (or WFS2) (i.e., the grating RG), which makes it possible to measure the position of the fine motion stage WFS1 (or WFS2) with high accuracy using the fine motion stage position measuring system 70A. In addition, as a result, the main control apparatus 20 can drive the fine motion stage WFS1 (or WFS2) with high accuracy via the coarse motion stage drive system 51A and/or the fine motion stage drive system 52A.

In addition, in this case, the irradiation point on the grating RG of each measurement beam emerging from the measuring arm 71A of each head of the encoder system 73 and the laser interferometer system 75—such systems constituting the fine motion stage position measuring system 70A—coincides with the center (i.e., the exposure position) of the irradiation area IA (i.e., the exposure area) of the exposure light IL radiated to the wafer W. Accordingly, the main control apparatus 20 can measure the position of the fine motion stage WFS1 (or WFS2) with high accuracy without being affected by so-called Abbé error. In addition, disposing the measuring arm 71A directly below the grating RG makes it possible to greatly shorten the in-air optical path lengths of the measurement beams of the heads of the encoder system 73, which in turn reduces the effects of air turbulence and also makes it possible to measure the position of the fine motion stage WFS1 (or WFS2) with high accuracy.

In addition, in the present embodiment, the measurement station 300 is provided with the fine motion stage position measuring system 70B, which is configured such that it is bilaterally symmetric with the fine motion stage position measuring system 70A. Furthermore, in the measurement station 300, when the alignment systems ALL AL2₁-AL2₄ and the like perform the wafer alignment on the wafer W on the fine motion stage WFS2 (or WFS1) held by the coarse motion stages WCS2, the fine motion stage position measuring system 70B measures with high accuracy the position of the fine motion stage WFS2 (or WFS1), which is moveably held by the coarse motion stages WCS2, within the XY plane. As a result, the main control apparatus 20 can drive the fine motion stage WFS2 (or WFS1) with high accuracy via the coarse motion stage drive system 51B and/or the fine motion stage drive system 52B.

Accordingly, for example, by exposing the wafer W with the illumination light IL, the pattern can be formed accurately over the entire surface of the wafer W.

In addition, according to the present embodiment, the transfer of the fine motion stage WFS2 (or WFS1), which holds the unexposed wafer, from the coarse motion stages WCS2 to the relay stage DRST as well as from the relay stage DRST to the coarse motion stages WCS1 is accomplished by sliding the fine motion stage WFS2 (or WFS1) along the upper end surfaces (upper surfaces) of the coarse motion stages WCS2, the relay stage DRST, and the coarse motion stages WCS1 (i.e., along a plane parallel to the XY plane that includes the pair of stator parts 93a, 93b, namely along the first plane). In addition, the transfer of the fine motion stage WFS1 (or WFS2), which holds the exposed wafer, from the coarse motion stages WCS1 to the relay stage DRST as well as from the relay stage DRST to the coarse motion stage WCS2 is accomplished by moving the fine motion stage WFS1 (or WFS2) in the internal spaces of the coarse motion stages WCS1, the relay stage DRST, and the coarse motion stages WCS2 that are positioned on the −Z side of the first plane. Accordingly, the transfer of the wafer between the coarse motion stages WCS1 and the relay stage DRST as well as between the coarse motion stages WCS2 and the relay stage DRST can be achieved while minimizing any increase in the footprint of the apparatus.

In addition, in the abovementioned embodiment, despite the fact that the relay stage DRST is configured moveably within the XY plane, in the actual sequence, the relay stage DRST stands by at the standby position discussed above, as is clear from the explanation of the sequence of parallel process operations discussed above. This also minimizes any increase in the footprint of the apparatus.

In addition, according to the exposure apparatus 100 of the present embodiment, the fine motion stage WFS1 (or WFS2) can be accurately driven, which makes it possible to accurately drive the wafer W mounted an the fine motion stage WFS1 (or WFS2) synchronously with the reticle stage RST (i.e., the reticle R) and thereby to accurately transfer the pattern on the reticle R to the wafer W via a scanning exposure. In addition, in the exposure apparatus 100 of the present embodiment, it is possible to perform a wafer exchange on the fine motion stage WFS2 (or WFS1), an alignment measurement on the exchanged wafer W, and the like at the measurement station 300 in parallel with the performance of an exposure operation on the wafer W mounted on the fine motion stage WFS1 (or WFS2) at the exposure station 200, which makes it possible to improve throughput more than is the case when the wafer exchange, alignment measurement, and exposure processes are performed sequentially.

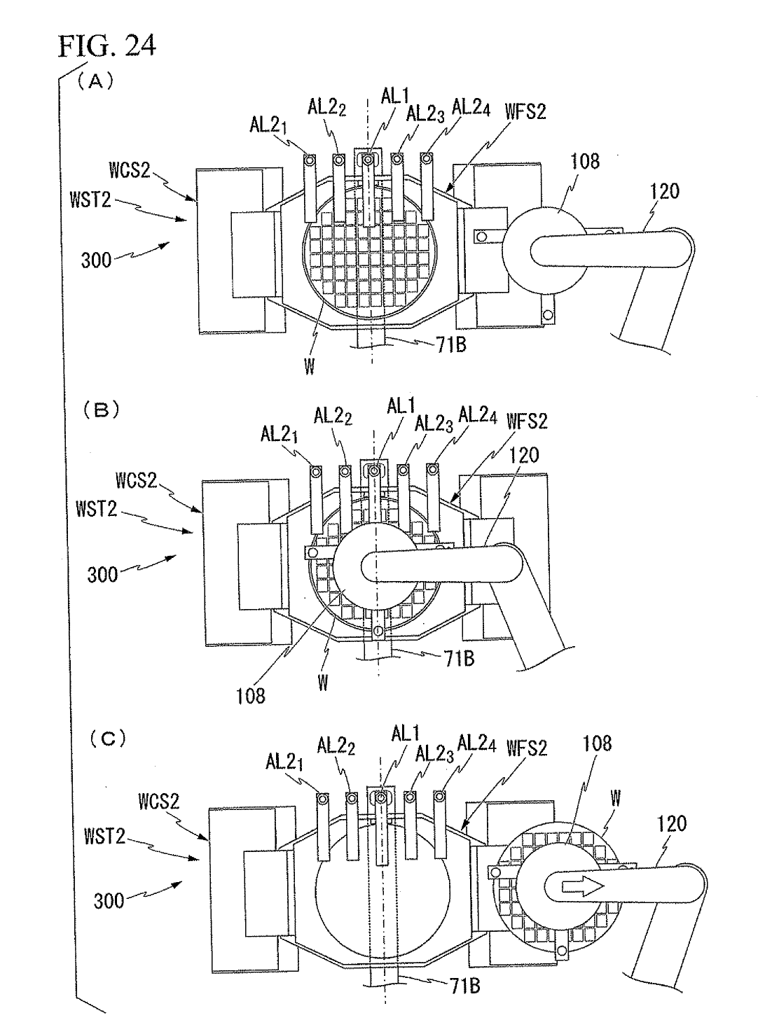

Furthermore, the abovementioned embodiment explained a case wherein the wafer exchange on the fine motion stage WFS1 or WFS2 is performed by the cooperation of the chuck unit 102, which comprises the Bernoulli chuck 108 that moves vertically by the drive part 104, and the wafer transport arm 118, but the present invention is not limited thereto. For example, as in the modified example shown in FIG. 24(A), a transport apparatus may be configured by fixing the Bernoulli chuck 108 to a tip of a vertically moveable horizontal polyarticular robot arm 120 (hereinbelow abbreviated as “robot arm”).

In the case of the transport apparatus configured as shown in FIG. 24(A), the wafer exchange is performed via the procedure below.

Assuming that the wafer exchange has begun, the fine motion stage WFS2, which holds the exposed wafer W, is located at the wafer exchange position below the chuck unit 102 and is supported by the coarse motion stages WCS2 (refer to FIG. 24(A)). In addition, the Bernoulli chuck 108 stands by at a prescribed standby position (refer to FIG. 24(A)).

First, the main control apparatus 20 controls the robot arm 120 so as to drive the Bernoulli chuck 108 downward. During this drive, the main control apparatus 20 controls the robot arm 120 and the Bernoulli chuck 108 in accordance with the measurement values of a gap sensor using the same procedure as discussed above. Thereby, the Bernoulli chuck 108 noncontactually chucks the wafer W from above with a clearance of approximately several microns (refer to FIG. 24(B)).

Furthermore, the main control apparatus 20 controls the robot arm 120 so as to lift the Bernoulli chuck 108, which noncontactually chucks the wafer W, upward and then drive it within the horizontal plane. Thereby, the wafer W is transported to the wafer unloading position, which is spaced apart from the wafer exchange position in the +X direction, and then mounted at the wafer unloading position. FIG. 24(C) shows an aspect wherein the robot arm 120 is moving away from the wafer exchange position.

Next, the main control apparatus 20 performs the loading of a new (i.e., unexposed) wafer W on the fine motion stage WFS2 using a procedure that is roughly the reverse of that for the abovementioned unloading, and therefore the details thereof are omitted. In this case as well, based on the information regarding the rotational error and the positional deviation in the X axial directions and the Y axial directions of the wafer W supplied from the signal processing system 116 discussed above, the main control apparatus 20 uses the fine motion stage drive system 52B (and the coarse motion stage drive system 51B) to adjust, based on the measurement values of the relative position measuring instrument 22B and the wafer stage position measuring system 16B, the position within the XY plane (including θz rotation) of the fine motion stage WFS2 such that the rotational error and positional deviation of the wafer W are corrected.

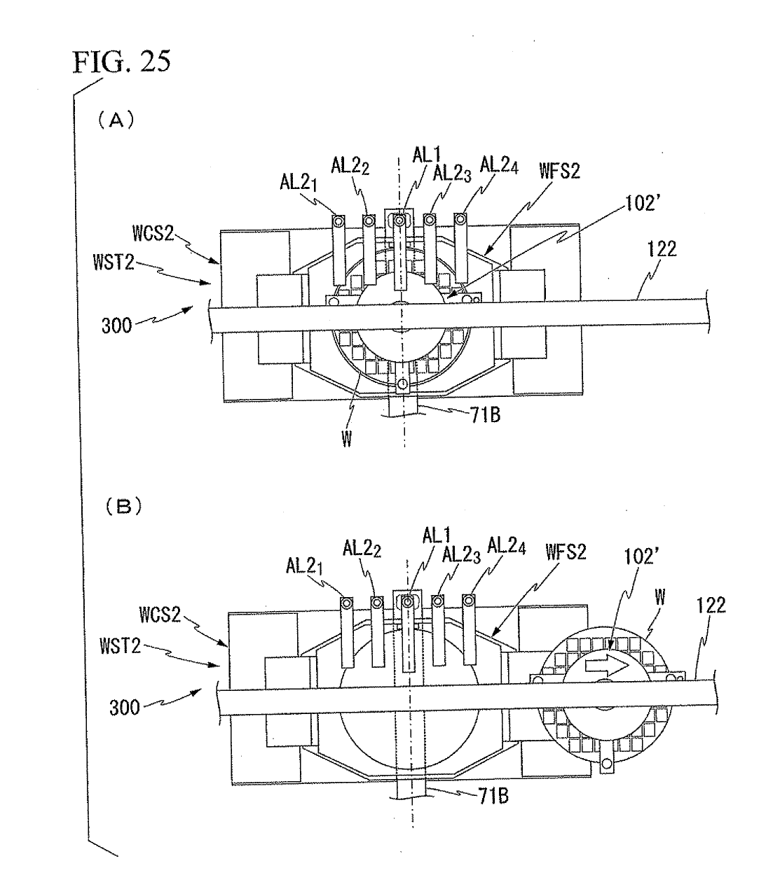

In addition, as shown in FIG. 25(A), a configuration may be adopted wherein a chuck unit 102′ that is configured identically to (and preferably lighter than) the chuck unit 102 is capable of being driven along a guide 122. In the transport apparatus according to the modified example shown in FIG. 25(A), the main control apparatus 20 controls the Bernoulli chuck 108 (refer to FIG. 25(A)) such that the Bernoulli chuck 108 chucks the wafer W noncontactually from above through a procedure identical to that used in the embodiment discussed above. Next, the main control apparatus 20 drives the Bernoulli chuck 108, which noncontactually chucks the wafer W, upward and transports the Bernoulli chuck 108 toward the wafer unloading position along the guide 122 (refer to FIG. 25(B)).

Next, the main control apparatus 20 loads the new (i.e., unexposed) wafer W on the fine motion stage WFS2 (not shown in detail) using a procedure that is roughly the reverse of that used in the abovementioned unloading. In this case, too, the positional deviation and rotational error of the wafer W are corrected as discussed above.

Furthermore, the abovementioned embodiment explained a case wherein the three image capturing devices 114a-114c are provided in order to adjust the positional deviation and rotational error when the wafer is loaded, but the present invention is not limited thereto; for example, a detection system that detects a mark (or a pattern) on the wafer, or multiple microscopes that each comprise a CCD and the like, may be provided. In this case, the main control apparatus 20 would be able to detect the positions of three or more marks using the multiple microscopes and derive the positional deviation and rotational error of the wafer W by performing prescribed statistical calculations on those detection results.

Furthermore, in the abovementioned embodiment, instead of the Bernoulli chuck 108, it is possible to use a chuck member that is capable of noncontactually holding the wafer W from above, such as a chuck member that takes advantage of differential pumping as in, for example, a vacuum preloaded aerostatic bearing.

In addition, the abovementioned embodiment explained the case wherein the relay stage DRST is provided in addition to the coarse motion stages WCS1, WCS2, but the relay stage does not necessarily have to be provided. In such a case, for example, the fine motion stage may be transferred between the coarse motion stages WCS2 and the coarse motion stages WCS1 directly; alternatively, a robot arm and the like, for example, may transfer the fine motion stage to the coarse motion stages WCS1, WCS2. In the former case, for example, the coarse motion stages WCS2 may be provided with a transport mechanism that transfers the fine motion stage to the coarse motion stages WCS1, receives the fine motion stage from the coarse motion stages WCS1, and transfers the fine motion stage to an external transport system (not shown). In this case, the external transport system should mount the fine motion stage that holds the wafer on the coarse motion stages WCS2. If the relay stage is not provided, then the footprint of the apparatus can be reduced commensurately.

Furthermore, the abovementioned embodiment explained a case wherein the fine motion stage position measuring systems 70A, 70B are made entirely of, for example, glass and comprise the measuring arms 71A, 71B, wherethrough light can travel, but the present invention is not limited thereto. For example, the measuring arms may have a hollow structure wherein at least the portions wherethrough each of the laser beams travel, which was discussed above, may be formed as solid members wherethrough light can travel, and the other portions may be formed as, for example, members that do not transmit light. In addition, for example, the measuring arms may be configured such that the light source, the photodetector, and the like are built into the tip parts of the measuring arms as long as the measurement beams can be radiated from the portion that opposes the grating RG. In such a case, the measurement beams of the encoders would not have to travel through the interior of the measuring arms. Furthermore, the shape of the measuring arms does not particularly matter. In addition, the fine motion stage position measuring systems 70A, 70B do not necessarily have to comprise the measuring arms, respectively, and may have some other configuration as long as each comprises a head disposed such that it opposes the grating RG disposed in the spaces of the coarse motion stages WCS1, WCS2, radiates at least one measurement beam to the grating RG, and receives a diffracted beam of the measurement beam from the grating RG, and as long as the position of the fine motion stage WFS1 (or WFS2) can be measured at least within the XY plane based on the output of that head.

In addition, the abovementioned embodiment explained an exemplary case wherein the encoder system 73 comprises the X head 77x and the pair of Y heads 77ya, 77yb, but the present invention is not limited thereto; for example, one or two two-dimensional heads (i.e., 2D heads), whose measurement directions are in two directions, namely, the X axial directions and the Y axial directions, may be provided. If two 2D heads are provided, then their detection points may be two points that are equidistantly spaced apart from the center of the exposure position on the grating in the X axial directions.

Furthermore, in the abovementioned embodiment, the grating RG is disposed on the upper surface of the fine motion stage WFS1 (or WFS2), namely, on the surface that opposes the wafer W, but the present invention is not limited thereto; for example, the grating may be formed in the wafer holder, which holds the wafer. In such a case, even if the wafer holder expands during an exposure or if a mounting position deviates with respect to the fine motion stages, it is possible to track this deviation and still measure the position of the wafer holder (i.e., the wafer). In addition, the grating may be disposed on the lower surface of the fine motion stage; in such a case, the measurement beams radiated from the encoder heads would not travel through the interior of the fine motion stages and, therefore, the fine motion stages would not have to be solid members wherethrough the light can transmit, the interior of the fine motion stages could have a hollow structure wherein piping, wiring, and the like could be disposed, and thereby the fine motion stages could be made more lightweight.

In addition, the drive mechanisms (52A, 52B) that drive the fine motion stages WFS1, WFS2 with respect to the coarse motion stages WCS1 or WCS2 is not limited to the one explained in the abovementioned embodiment. For example, in the abovementioned embodiment, the coils that drive the fine motion stages in the Y axial directions also function as the coils that drive the fine motion stages in the Z axial directions, but the present invention is not limited thereto; for example, actuators (i.e., linear motors) that drive the fine motion stages in the Y axial directions and actuators that drive, namely, levitate, the fine motion stages in the Z axial directions may be separately provided. In such a case, because a constant levitational force can be applied continuously to the fine motion stages, the position of the fine motion stages in the Z axial directions is stable.

Furthermore, in the abovementioned embodiment, the coarse motion stages WCS1 or WCS2 support the fine motion stages WFS1, WFS2 noncontactually by virtue of the action of Lorentz's forces (i.e., electromagnetic forces), but the present invention is not limited thereto; for example, a vacuum boosted aerostatic bearing and the like may be provided to the fine motion stages WFS1, WFS2, and the coarse motion stages WCS1 or WCS2 may levitationally support the fine motion stages WFS1, WFS2. In addition, in the abovementioned embodiment, the fine motion stages WFS1, WFS2 can be driven in directions corresponding to a total of six degrees of freedom, but the present invention is not limited thereto; for example, any number of degrees of freedom is acceptable as long as the fine motion stages WFS1, WFS2 can move at least within a two dimensional plane that is parallel to the XY plane. In addition, each of the fine motion stage drive systems 52A, 52B is not limited to the moving magnet type discussed above and may be a moving coil type. Furthermore, the fine motion stages WFS1, WFS2 may be supported contactually by the coarse motion stages WCS1 or WCS2. Accordingly, the fine motion stage drive systems that drive the fine motion stages WFS1, WFS2 with respect to the coarse motion stages WCS1 or WCS2 may each comprise a combination of, for example, a rotary motor and a ball screw (or a feed screw).

Furthermore, the abovementioned embodiment explained a case wherein the exposure apparatus is a liquid immersion type exposure apparatus, but the present invention is not limited thereto; for example, the present invention can be suitably adapted also to a dry type exposure apparatus that exposes the wafer W without transiting any liquid (i.e., water).

Furthermore, the abovementioned embodiment explained a case wherein the present invention is adapted to a scanning stepper, but the present invention is not limited thereto; for example, the present invention may also be adapted to a static type exposure apparatus, such as a stepper. Unlike the case wherein encoders measure the position of a stage whereon an object to be exposed is mounted and the position of the stage is measured using an interferometer, it is possible, even in the case of a stepper and the like, to reduce the generation of position measurement errors owing to air turbulence to virtually zero, and therefore to position the stage with high accuracy based on the measurement values of the encoder; as a result, a reticle pattern can be transferred with high accuracy to an object. In addition, the present invention can also be adapted to a step-and-stitch type reduction projection exposure apparatus that stitches shot regions together.

In addition, the projection optical system in the exposure apparatus 100 of the embodiment mentioned above is not limited to a reduction system and may be a unity magnification system or an enlargement system; furthermore, the projection optical system PL is not limited to a dioptric system and may be a catoptric system or a catadioptric system; in addition, the image projected thereby may be either an inverted image or an erect image.

In addition, the illumination light IL is not limited to ArF excimer laser light (with a wavelength of 193 nm), but may be ultraviolet light, such as KrF excimer laser light (with a wavelength of 248 nm), or vacuum ultraviolet light, such as F₂ laser light (with a wavelength of 157 nm). For example, as disclosed in U.S. Pat. No. 7,023,610, higher harmonics may also be used as the vacuum ultraviolet light by utilizing, for example, an erbium (or erbium-ytterbium) doped fiber amplifier to amplify single wavelength laser light in the infrared region or the visible region that is generated from a DFB semiconductor laser or a fiber laser, and then using a nonlinear optical crystal for wavelength conversion to convert the output laser light to ultraviolet light.

In addition, the illumination light IL of the exposure apparatus 100 in the abovementioned embodiment is not limited to light with a wavelength of 100 nm or greater, and, of course, light with a wavelength of less than 100 nm may be used. For example, the present invention can be adapted to an EUV exposure apparatus that uses extreme ultraviolet (EUV) light in the soft X-ray region (e.g., light in a wavelength band of 5-45 nm). In addition, the present invention can also be adapted to an exposure apparatus that uses a charged particle beam, such as an electron beam or an ion beam.

In addition, in the embodiment discussed above an optically transmissive mask (i.e., a reticle) wherein a prescribed shielding pattern (or a phase pattern or dimming pattern) is formed on an optically transmissive substrate is used; however, instead of such a reticle, an electronic mask—including variable shaped masks, active masks, and digital micromirror devices (DMDs), which are also called image generators and are one type of non-light emitting image display devices (i.e., spatial light modulators)—may be used wherein a transmissive pattern, a reflective pattern, or a light emitting pattern is formed based on electronic data of the pattern to be exposed, as disclosed in, for example, U.S. Pat. No. 6,778,257. In the case wherein a variable shaped mask is used, the stage whereon the wafer, a glass plate, or the like is mounted is scanned with respect to the variable shaped mask, and therefore effects equivalent to those of the above-mentioned embodiment can be obtained by using the encoder system and a laser interferometer system to measure the position of the stage.

In addition, by forming interference fringes on the wafer W as disclosed in, for example, PCT International Publication No. WO2001/035168, the present invention can also be adapted to an exposure apparatus (i.e., a lithographic system) that forms a line-and-space pattern on the wafer W.

Furthermore, the present invention can also be adapted to, for example, an exposure apparatus that combines the patterns of two reticles onto a wafer via a projection optical system and double exposes, substantially simultaneously, a single shot region on the wafer using a single scanning exposure, as disclosed in, for example, U.S. Pat. No. 6,611,316.

Furthermore, in the abovementioned embodiment, the object whereon the pattern is to be formed (i.e., the object to be exposed by being irradiated with an energy beam) is not limited to a wafer, and may be a glass plate, a ceramic substrate, a film member, or some other object such as a mask blank.

The application of the exposure apparatus 100 is not limited to an exposure apparatus for fabricating semiconductor devices, but can be widely adapted to, for example, an exposure apparatus for fabricating liquid crystal devices, wherein a liquid crystal display device pattern is transferred to a rectangular glass plate, as well as to exposure apparatuses for fabricating organic electroluminescent displays, thin film magnetic heads, image capturing devices (e.g., CCDs), micromachines, and DNA chips. In addition to fabricating microdevices like semiconductor devices, the present invention can also be adapted to an exposure apparatus that transfers a circuit pattern to a glass substrate, a silicon wafer, or the like in order to fabricate a reticle or a mask used by a light exposure apparatus, an EUV exposure apparatus, an X-ray exposure apparatus, an electron beam exposure apparatus, and the like.

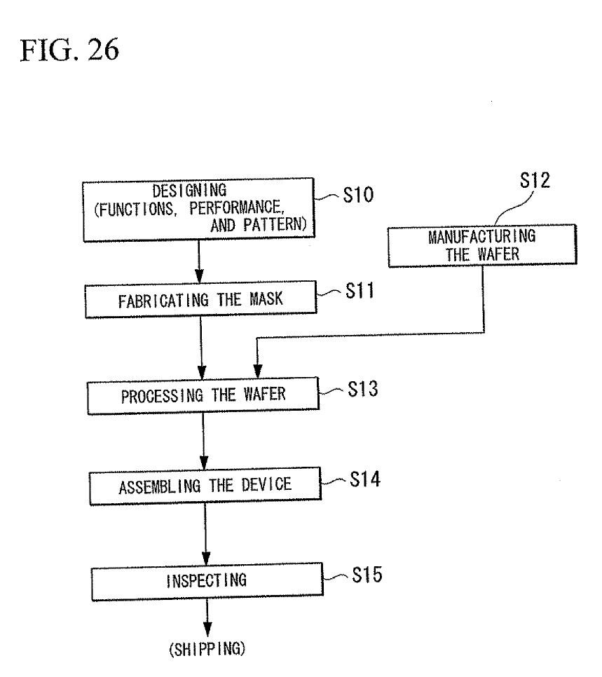

The following text explains an embodiment of a method of fabricating microdevices using the exposure apparatus and the exposing method according to the embodiments of the present invention in a lithographic process. FIG. 26 depicts a flow chart of an example of fabricating a microdevice (i.e., a semiconductor chip such as an IC or an LSI; a liquid crystal panel; a CCD; a thin film magnetic head; a micromachine; and the like).

First, in a step S10 (i.e., a designing step), the functions and performance of the microdevice (e.g., the circuit design of the semiconductor device), as well as the pattern for implementing those functions, are designed. Next, in a step S11 (i.e., a mask fabricating step), the mask (i.e., the reticle), wherein the designed circuit pattern is formed, is fabricated. Moreover, in a step S12 (i.e., a wafer manufacturing step), the wafer is manufactured using a material such as silicon.

Next, in a step S13 (i.e., a wafer processing step), the actual circuit and the like are formed on the wafer by, for example, lithographic technology (discussed later) using the mask and the wafer that were prepared in the steps S10 to S12. Then, in a step S14 (i.e., a device assembling step), the device is assembled using the wafer that was processed in the step S13. In the step S14, processes are included as needed, such as the dicing, bonding, and packaging (i.e., chip encapsulating) processes. Lastly, in a step S15 (i.e., an inspecting step), inspections are performed, for example, an operation verification test and a durability test of the microdevice fabricated in the step S14. Finishing such processes completes the fabrication of the microdevice, which is then shipped.

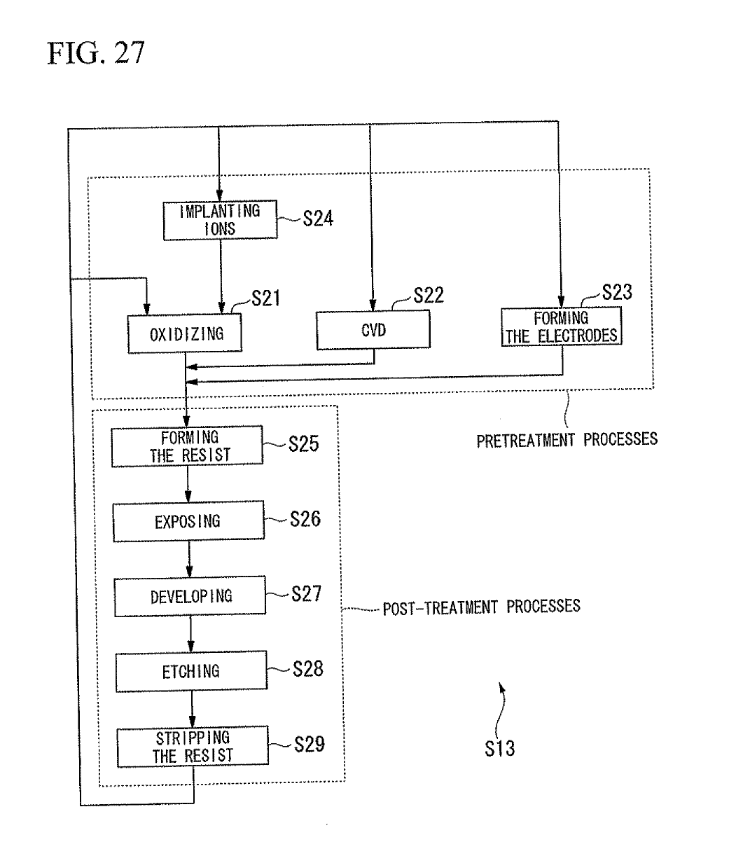

FIG. 27 depicts one example of the detailed process of the step S13 for the case of a semiconductor device.

In a step S21 (i.e., an oxidizing step), the front surface of the wafer is oxidized. In a step S22 (i.e., a CVD step), an insulating film is formed on the front surface of the wafer. In a step S23 (i.e., an electrode forming step), an electrode is formed on the wafer by vacuum deposition. In a step S24 (i.e., an ion implanting step), ions are implanted in the wafer. The above steps S21-S24 constitute the pretreatment processes of the various stages of wafer processing and are selectively performed in accordance with the processes needed in the various stages.

When the pretreatment processes discussed above in each stage of the wafer process are complete, post-treatment processes are performed as described below. In the post-treatment processes, the wafer is first coated with a photosensitive agent in a step S25 (i.e., a resist forming step). Continuing, in a step S26 (i.e., an exposing step), the circuit pattern of the mask is transferred onto the wafer by the lithography system (i.e., the exposure apparatus) and the exposing method explained above. Next, in a step S27 (i.e., a developing step), the exposed wafer is developed; further, in a step S28 (i.e., an etching step), the uncovered portions are removed by etching, excluding the portions where the resist remains. Further, in a step S29 (i.e., a resist stripping step), etching is finished and the resist that is no longer needed is stripped. Circuit patterns are superposingly formed on the wafer by repetitively performing the pretreatment and post-treatment processes.

As explained above, the exposure apparatus, the exposing method, and the device fabricating method of the present invention are each adapted to either the loading of a thin plate shaped object onto a holding apparatus or the unloading of the thin plate shaped object from the holding apparatus, or both. In addition, the exposing method and the exposure apparatus of the present invention are suitable for forming a pattern on an object by radiating an energy beam thereto. In addition, the device fabricating method of the present invention is suitable for fabricating electronic devices. In addition, the transport system of the present invention is adapted to transporting the thin plate shaped object.

In one embodiment, moving the two second moving bodies along the guide members in directions away from one another makes it possible to easily release the holding apparatus from the support of the two second moving bodies with the object held as is, and thus to uncouple the holding apparatus from the two second moving bodies.

In addition, it becomes possible to load the object onto the holding apparatus while using a transport member to noncontactually hold the object from above. Consequently, to load the object onto the holding apparatus, there is no need to form a notch in the holding apparatus for the purpose of housing an arm and the like used in that loading; in addition, there is no need to provide a vertically moving member to the holding apparatus for the purpose of transferring the object.

1. An exposure apparatus that radiates an energy beam to form a pattern on an object, comprising:
a first moving body, which comprises guide members that extend in a first direction, that moves in a second direction, which is substantially orthogonal to the first direction;
two second moving bodies, which are provided such that they are capable of moving in the first direction along the guide members, that move in the second direction together with the guide members by the movement of the first moving body;
a holding apparatus, which holds the object and is supported by the two second moving bodies such that it is capable of moving within a two dimensional plane that includes at least the first direction and the second direction; and
a transport apparatus, which comprises a chuck member that can noncontactually hold the object from above, that transports the object to and from the holding apparatus.

2. An exposure apparatus according to claim 1, wherein
the chuck member is a Bernoulli chuck that uses the Bernoulli effect to noncontactually hold the object.

3. An exposure apparatus according to claim 1, wherein
the transport apparatus comprises:
a first member, which is provided with the chuck member and moves vertically at a first position in a direction orthogonal to the prescribed plane; and
a second member, which transfers the object to and from the first member and is capable of moving within an area of a prescribed range that includes the first position and a second position that is spaced apart from the first position along a direction parallel to the two dimensional plane.

4. An exposure apparatus according to claim 1, wherein
the transport apparatus comprises a transport member, which is provided with the chuck member and is capable of moving in a direction orthogonal to the prescribed plane and in a direction parallel to the prescribed plane.

5. An exposure apparatus according to claim 1, wherein
the transport apparatus comprises a gap sensor, which is provided to the chuck member, that detects a spacing between the chuck member and an upper surface of the object held by the holding apparatus; and
the exposure apparatus further comprising:
a regulating apparatus that, based on a detection result of the gap sensor, regulates a distance between the chuck member and the object.

6. An exposure apparatus according to claim 1, wherein
the transport apparatus comprises a measuring system, which is provided to the chuck member, that measures the position of the object held by the chuck member;
the exposure apparatus further comprising:
an adjusting apparatus that adjusts the position of the holding apparatus based on the result of the position measurement.

7. An exposure apparatus according to claim 1, wherein
a measurement surface is provided to one surface of the holding apparatus that is substantially parallel to the two dimensional plane; and
a space is provided inside the second moving bodies;
the exposure apparatus further comprising:
a first measuring system that comprises a head part, which is disposed opposing the measurement surface in the space of the second moving bodies, radiates at least one first measurement beam to the measurement surface, receives light of the first measurement beam reflected from the measurement surface, and that measures the position of the holding apparatus at least within the two dimensional plane based on an output of the head part; and
a drive system that drives the holding apparatus independently or integrally with the moving body based on the position measured by the first measuring system.

8. An exposing method that radiates an energy beam to form a pattern on an object, the method comprising:
moving a first moving body, which comprises guide members that extend in a first direction, in a second direction, which is orthogonal to the first direction;
moving two second moving bodies, which are provided such that they are capable of moving in the first direction along the guide members, in the second direction together with the guide members by the movement of the first moving body;
supporting a holding apparatus, which holds the object, by the two second moving bodies, synchronously moves the two second moving bodies along the guide members, and moves the holding apparatus in the first direction; and
using a chuck member, which is capable of noncontactually holding the object from above, to transport the object to and from the holding apparatus.

9. An exposing method according to claim 8, wherein
the chuck member is a Bernoulli chuck that uses the Bernoulli effect to noncontactually hold the object.

10. An exposing method according to claim 8, further comprising:
prior to the chuck member holding the object, transporting the object by a transport member to below the chuck member above the holding apparatus.

11. An exposing method according to claim 8, further comprising:
using a gap sensor, which is provided to the chuck member, to detect a spacing between an upper surface of the object held by the holding apparatus and the chuck member; and
regulating a distance between the chuck member and the object based on a detection result of the gap sensor.

12. An exposing method according to claim 8, further comprising:
measuring the position of the object held by the chuck member by a measuring system, which is provided to the chuck member; and
adjusting the position of the holding apparatus based on the position measurement result.

13. A device fabricating method, comprising:
exposing an object using an exposing method according to claim 8; and
developing the exposed object.
